(19) United States
(12) Patent Application Publication
(10) Pub. No.: US 2025/0063894 A1
(43) Pub. Date: Feb. 20, 2025

(54) DISPLAY DEVICE AND METHOD OF MANUFACTURING THE SAME

(71) Applicant: Samsung Display Co., Ltd., Yongin-Si (KR)

(72) Inventors: Seon Young CHOI, Yongin-si (KR); Gyung Soon PARK, Yongin-si (KR)

(21) Appl. No.: 18/755,723

(22) Filed: Jun. 27, 2024

(30) Foreign Application Priority Data
Aug. 16, 2023 (KR) 10-2023-0107162

(51) Int. Cl. H10K 59/122; H10K 59/12; H10K 59/80

(52) U.S. Cl. CPC H10K 59/122; H10K 59/1201; H10K 59/873

(57) ABSTRACT

A display device comprises a first pixel electrode disposed on a substrate in a first emission area, an insulating layer covering edges of the first pixel electrode, a first light emitting layer disposed on the first pixel electrode and the insulating layer, a first common electrode disposed on the first light emitting layer, a conductive layer disposed on the insulating layer to surround the first emission area and contact the first common electrode, a first bank disposed on the conductive layer, a second bank disposed on the first bank and including tips protruding from side surfaces of the first bank toward the first emission area, and a third bank disposed on the second bank and including an inorganic material.

This application claims the benefit of Korean Patent Application No. 10-2023-0107162 filed on Aug. 16, 2023, in the Korean Intellectual Property Office, the disclosure of which is incorporated herein in its entirety by reference.

### BACKGROUND

### 1. Field

The present disclosure relates to a display device and a method of manufacturing the same.

### 2. Description of the Related Art

As the information society develops, demands for display devices for displaying images are increasing in various forms. For example, display devices are applied to various electronic devices such as smartphones, digital cameras, notebook computers, navigation devices, and smart televisions. The display devices may be flat panel display devices such as liquid crystal display devices, field emission display devices, and organic light emitting display devices. Among these flat panel display devices, a light emitting display device includes a light emitting element that enables each pixel of a display panel to emit light by itself. Thus, the light emitting display device can display an image without a backlight unit that provides light to the display panel.

### SUMMARY

Aspects of the present disclosure provide a display device capable of improving the reliability of light emitting elements by blocking a moisture penetration path and a method of manufacturing the display device.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an embodiment, a display device comprises a first pixel electrode disposed on a substrate in a first emission area, an insulating layer covering edges of the first pixel electrode, a first light emitting layer disposed on the first pixel electrode and the insulating layer, a first common electrode disposed on the first light emitting layer, a conductive layer disposed on the insulating layer to surround the first emission area and contact the first common electrode, a first bank disposed on the conductive layer, a second bank disposed on the first bank and including tips protruding from side surfaces of the first bank toward the first emission area, and a third bank disposed on the second bank and including an inorganic material.

The display device may further comprise a fourth bank disposed on the third bank and including a metal material.

A thickness of the first bank may be greater than the sum of thicknesses of the second bank, the third bank, and fourth bank, and the thickness of the third bank may be greater than the thickness of each of the second and fourth banks.

The display device may further comprise a first organic pattern including the same material as the first light emitting layer and disposed on the fourth bank in an area adjacent to the first emission area, and a first electrode pattern including the same material as the first common electrode and disposed on the first organic pattern on the fourth bank.

The display device may further comprise a capping layer disposed on the first common electrode, and a first capping pattern including the same material as the capping layer and disposed on the first electrode pattern.

The display device may further comprise a first inorganic layer covering the side surfaces of the first bank, lower and side surfaces of the tips of the second bank, side surfaces of the third and fourth banks, side surfaces of the first organic pattern, side surfaces of the first electrode pattern, and upper and side surfaces of the first capping pattern.

The display device may further comprise a second pixel electrode disposed on the substrate in a second emission area, a second light emitting layer disposed on the second pixel electrode, and a second common electrode disposed on the second light emitting layer to contact the conductive layer.

The first and second common electrodes may be electrically connected through the conductive layer.

The display device may further comprise a capping layer disposed on the second common electrode, a second organic pattern including the same material as the second light emitting layer and disposed on the fourth bank in an area adjacent to the second emission area, a second electrode pattern including the same material as the second common electrode and disposed on the second organic pattern on the fourth bank, and a second capping pattern including the same material as the capping layer and disposed on the second electrode pattern.

The display device may further comprise a second inorganic layer covering the side surfaces of the first bank, the lower and side surfaces of the tips of the second bank, the side surfaces of the third and fourth banks, side surfaces of the second organic pattern, side surfaces of the second electrode pattern, and upper and side surfaces of the second capping pattern.

The display device may further comprise a capping layer disposed on the first common electrode, a first organic pattern including the same material as the first light emitting layer and disposed on the third bank in an area adjacent to the first emission area, a first electrode pattern including the same material as the first common electrode and disposed on the first organic pattern on the third bank, and a first capping pattern including the same material as the capping layer and disposed on the first electrode pattern.

The display device may further comprise a fourth bank disposed on the third bank and including a different inorganic material from the third bank.

The display device may further comprise a fourth bank disposed on the third bank, and a fifth bank disposed on the fourth bank and protruding from side surfaces of the fourth bank toward the first emission area.

According to an embodiment, a display device comprises a first pixel electrode disposed on a substrate in a first emission area, a second pixel electrode disposed on the same layer as the first pixel electrode in a second emission area, an insulating layer covering edges of each of the first and second pixel electrodes, a first light emitting layer disposed on the first pixel electrode and the insulating layer, a first common electrode disposed on the first light emitting layer, a second light emitting layer disposed on the second pixel electrode and the insulating layer, a second common electrode disposed on the second light emitting layer, a conductive layer disposed on the insulating layer to surround each of the first and second emission areas and electrically connect the first and second common electrodes, a first bank disposed on the conductive layer, a second bank disposed on the first bank and including tips protruding from side surfaces of the first bank toward each of the first and second emission areas, a third bank disposed on the second bank, and a fourth bank disposed on the third bank and including tips protruding from side surfaces of the third bank toward each of the first and second emission areas.

The display device may further comprise a capping layer disposed on the first common electrode, a first organic pattern including the same material as the first light emitting layer and disposed on the fourth bank in an area adjacent to the first emission area, a first electrode pattern including the same material as the first common electrode and disposed on the first organic pattern on the fourth bank, a first capping pattern including the same material as the capping layer and disposed on the first electrode pattern, and a first inorganic layer covering the side surfaces of the first bank, lower and side surfaces of the tips of the second bank, side surfaces of the third bank, lower and side surfaces of the tips of the fourth bank, side surfaces of the first organic pattern, side surfaces of the first electrode pattern, and upper and side surfaces of the first capping pattern.

The display device may further comprise a capping layer disposed on the second common electrode, a second organic pattern including the same material as the second light emitting layer and disposed on the fourth bank in an area adjacent to the second emission area, a second electrode pattern including the same material as the second common electrode and disposed on the second organic pattern on the fourth bank, a second capping pattern including the same material as the capping layer and disposed on the second electrode pattern, and a second inorganic layer covering the side surfaces of the first bank, the lower and side surfaces of the tips of the second bank, the side surfaces of the third bank, lower and side surfaces of the tips of the fourth bank, side surfaces of the second organic pattern, side surfaces of the second electrode pattern, and upper and side surfaces of the second capping pattern.

According to an embodiment, a method of manufacturing a display device comprises forming pixel electrodes and sacrificial layers on a substrate, the pixel electrodes including a first pixel electrode which overlaps a first emission area and a second pixel electrode which overlaps a second emission area, sequentially stacking an insulating layer, a conductive layer, a first bank, a second bank, a third bank, and a fourth bank on the pixel electrodes, forming tips of the second bank which protrude from side surfaces of the first bank by etching the fourth bank, the third bank, the second bank, the first bank, and the conductive layer, exposing the first and second pixel electrodes by etching the insulating layer and the sacrificial layer, forming a first light emitting layer on the first pixel electrode and a first organic pattern on the fourth bank, forming a first common electrode on the first light emitting layer and a first electrode pattern on the first organic pattern on the fourth bank, forming a capping layer on the first common electrode and a first capping pattern on the first electrode pattern on the fourth bank, and forming a first inorganic layer which covers an upper surface of the capping layer, the side surfaces of the first bank, lower and side surfaces of the tips of the second bank, side surfaces of the third and fourth banks, side surfaces of the first organic pattern, side surfaces of the first electrode pattern, and upper and side surfaces of the first capping pattern.

The third bank and the first inorganic layer may include at least one of a silicon nitride layer, a silicon oxynitride layer, a silicon oxide layer, a titanium oxide layer, an aluminum oxide layer, and an amorphous silicon layer.

The method may further comprise etching the first inorganic layer, the first capping pattern, the first electrode pattern, and the first organic pattern which overlap the second emission area and the fourth bank disposed adjacent to the second emission area.

The method may further comprise forming a second light emitting layer on the second pixel electrode and a second organic pattern on the fourth bank, forming a second common electrode on the second light emitting layer and a second electrode pattern on the second organic pattern on the fourth bank, forming a capping layer on the second common electrode and a second capping pattern on the second electrode pattern on the fourth bank, and forming a second inorganic layer which covers an upper surface of the capping layer, the side surfaces of the first bank, the lower and side surfaces of the tips of the second bank, the side surfaces of the third and fourth banks, side surfaces of the second organic pattern, side surfaces of the second electrode pattern, and upper and side surfaces of the second capping pattern.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to an embodiment;

FIG. 2 is a cross-sectional view of the display device according to the embodiment;

FIG. 3 is a plan view of a display unit of the display device according to the embodiment;

FIG. 4 is a cross-sectional view illustrating pixels of the display device according to the embodiment;

FIG. 5 is an enlarged view of area A1 of FIG. 4;

FIG. 6 is a cross-sectional view illustrating pixels of a display device according to an embodiment;

FIG. 7 is an enlarged view of area A2 of FIG. 6;

FIG. 8 is a cross-sectional view illustrating pixels of a display device according to an embodiment;

FIG. 9 is an enlarged view of area A3 of FIG. 8;

FIG. 10 is a cross-sectional view illustrating pixels of a display device according to an embodiment;

FIG. 11 is an enlarged view of area A4 of FIG. 10;

FIG. 12 is a cross-sectional view illustrating pixels of a display device according to an embodiment;

FIG. 13 is an enlarged view of area A5 of FIG. 12;

FIGS. 14, 15, 16, 17, 18, 19, 20 and 21 are cross-sectional views illustrating a process of manufacturing a display device according to an embodiment;

FIG. 22 illustrates a virtual reality device including a display device according to an embodiment;

FIGS. 23 and 24 illustrate a head mounted display including a display device according to an embodiment;

FIG. 25 is a cross-sectional view illustrating pixels according to an embodiment in the display devices of FIGS. 22 through 24;

FIG. 26 is a cross-sectional view illustrating pixels according to an embodiment in the display devices of FIGS. 22 through 24;

FIG. 27 is a cross-sectional view illustrating pixels according to an embodiment in the display devices of FIGS. 22 through 24;

FIG. 28 is a cross-sectional view illustrating pixels according to an embodiment in the display devices of FIGS. 22 through 24; and

FIG. 29 is a cross-sectional view illustrating pixels according to an embodiment in the display devices of FIGS. 22 through 24.

### DETAILED DESCRIPTION

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods employing one or more of the disclosure disclosed herein. It is apparent, however, that various embodiments may be practiced without these specific details or with one or more equivalent arrangements. In other instances, structures and devices are shown in block diagram form in order to avoid unnecessarily obscuring various embodiments. Further, various embodiments may be different, but do not have to be exclusive nor limit the disclosure. For example, specific shapes, configurations, and characteristics of an embodiment may be used or implemented in other embodiments without departing from the disclosure.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not necessarily intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, detailed embodiments of the disclosure is described with reference to the accompanying drawings.

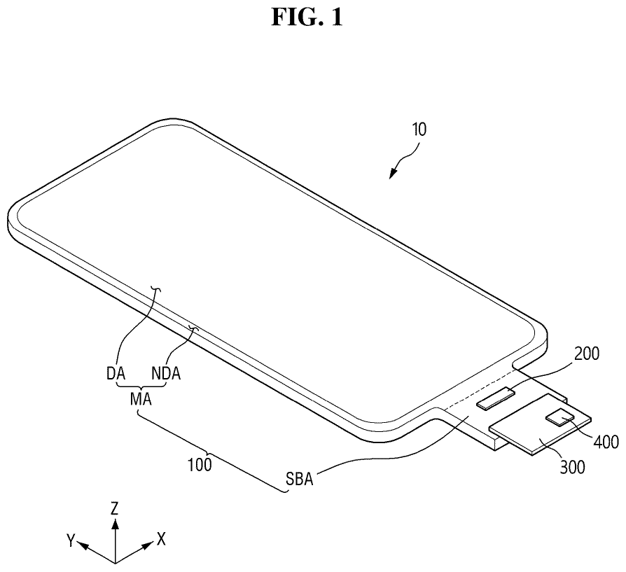

FIG. 1 is a perspective view of a display device 10 according to an embodiment.

Referring to FIG. 1, the display device 10 may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 may be applied as a display unit of a television, a notebook computer, a monitor, a billboard, or an Internet of things (IoT) device. For another example, the display device 10 may be applied to wearable devices such as smart watches, watch phones, glasses-type displays, and head mounted displays.

The display device 10 may have a planar shape similar to a quadrangle. For example, the display device 10 may have a planar shape similar to a quadrangle having short sides in an X-axis direction and long sides in a Y-axis direction. Each corner where a short side extending in the X-axis direction meets a long side extending in the Y-axis direction may be rounded with a predetermined curvature or may be right-angled. The planar shape of the display device 10 is not limited to the quadrangular shape but may also be similar to other polygonal shapes, a circular shape, or an oval shape.

The display device 10 may include a display panel 100, a display driver 200, a circuit board 300, and a touch driver 400.

The display panel 100 may include a main area MA and a sub-area SBA.

The main area MA may include a display area DA including pixels that display an image and a non-display area NDA disposed around the display area DA. The display area DA may emit light from a plurality of emission areas or a plurality of opening areas. For example, the display panel 100 may include pixel circuits including switching elements, a pixel defining layer defining the emission areas or the opening areas, and self-light emitting elements.

For example, each of the self-light emitting elements may include, but is not limited to, at least one of an organic light emitting diode including an organic light emitting layer, a quantum dot light emitting diode including a quantum dot light emitting layer, an inorganic light emitting diode including an inorganic semiconductor, and a micro light emitting diode.

The non-display area NDA may be an area outside the display area DA. The non-display area NDA may be defined as an edge area of the main area MA of the display panel 100. The non-display area NDA may include a gate driver (not illustrated) which supplies gate signals to gate lines and fan-out lines (not illustrated) which connect the display driver 200 and signal lines disposed in the display area DA.

The sub-area SBA may extend from a side of the main area MA. The sub-area SBA may include a flexible material that can be bent, folded, rolled, etc. For example, when the sub-area SBA is bent, it may be overlapped by the main area MA in a thickness direction (Z-axis direction). The sub-area SBA may include the display driver 200 and a pad unit connected to the circuit board 300. Optionally, the sub-area SBA may be omitted, and the display driver 200 and the pad unit may be disposed in the non-display area NDA.

The display driver 200 may output signals and voltages for driving the display panel 100. The display driver 200 may supply data voltages to data lines. The display driver 200 may supply a power supply voltage to a power line and supply a gate control signal to the gate driver. The display driver 200 may be formed as an integrated circuit and mounted on the display panel 100 by a chip on glass (COG) method, a chip on plastic (COP) method, or an ultrasonic bonding method. For example, the display driver 200 may be disposed in the sub-area SBA and may be overlapped with the main area MA in the thickness direction (Z-axis direction) by the bending of the sub-area SBA. For another example, the display driver 200 may be mounted on the circuit board 300.

The circuit board 300 may be connected to the pad unit of the display panel 100 using an anisotropic conductive film. Lead lines of the circuit board 300 may be electrically connected to the pad unit of the display panel 100. The circuit board 300 may be a flexible printed circuit board, a printed circuit board, or a flexible film such as a chip on film.

The touch driver 400 may be mounted on the circuit board 300. The touch driver 400 may be electrically connected to a touch sensing unit of the display panel 100. The touch driver 400 may supply a touch driving signal to a plurality of touch electrodes of the touch sensing unit and sense a change in capacitance between the touch electrodes. For example, the touch driving signal may be a pulse signal having a predetermined frequency. The touch driver 400 may determine whether an input has been made based on a change in capacitance between the touch electrodes and calculate coordinates of the input. The touch driver 400 may be formed as an integrated circuit.

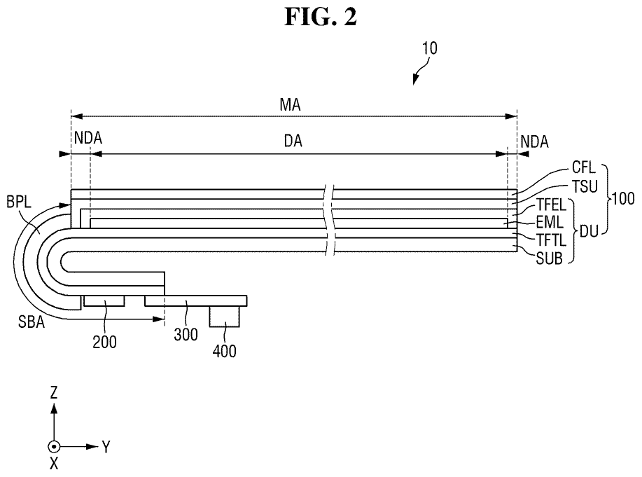

FIG. 2 is a cross-sectional view of the display device 10 according to the embodiment.

Referring to FIG. 2, the display panel 100 may include a display unit DU, a touch sensing unit TSU, and a color filter layer CFL. The display unit DU may include a substrate SUB, a thin-film transistor layer TFTL, a light emitting element layer EML, and an encapsulation layer TFEL.

The substrate SUB may be a base substrate or a base member. The substrate SUB may be a flexible substrate that can be bent, folded, rolled, etc. For example, the substrate SUB may include polymer resin such as polyimide (PI), but the present disclosure is not limited thereto. For another example, the substrate SUB may include a glass material or a metal material.

The thin-film transistor layer TFTL may be disposed on the substrate SUB. The thin-film transistor layer TFTL may include a plurality of thin-film transistors constituting pixel circuits of pixels. The thin-film transistor layer TFTL may further include gate lines, data lines, power lines, gate control lines, fan-out lines connecting the display driver 200 and the data lines, and lead lines connecting the display driver 200 and the pad unit. Each of the thin-film transistors may include a semiconductor region, a source electrode, a drain electrode, and a gate electrode. For example, when the gate driver is formed on a side of the non-display area NDA of the display panel 100, it may include thin-film transistors.

The thin-film transistor layer TFTL may be disposed in the display area DA, the non-display area NDA, and the sub-area SBA. The thin-film transistors of the pixels, the gate lines, the data lines, and the power lines of the thin-film transistor layer TFTL may be disposed in the display area DA. The gate control lines and the fan-out lines of the thin-film transistor layer TFTL may be disposed in the non-display area NDA. The lead lines of the thin-film transistor layer TFTL may be disposed in the sub-area SBA.

The light emitting element layer EML may be disposed on the thin-film transistor layer TFTL. The light emitting element layer EML may include a plurality of light emitting elements, each including a pixel electrode, a light emitting layer and a common electrode sequentially stacked to emit light, and a pixel defining layer defining the pixels. The light emitting elements of the light emitting element layer EML may be disposed in the display area DA.

For example, the light emitting layer may be an organic light emitting layer including an organic material. The light emitting layer may include a hole transporting layer, an organic light emitting layer, and an electron transporting layer. When the pixel electrode receives a predetermined voltage through a thin-film transistor of the thin-film transistor layer TFTL and the common electrode receives a cathode voltage, holes may move to the organic light emitting layer through the hole transporting layer, and electrons may move to the organic light emitting layer through the electron transporting layer. Then, the holes and the electrons may be combined with each other in the organic light emitting layer to emit light. For example, the pixel electrode may be an anode, and the common electrode may be a cathode, but the present disclosure is not limited thereto.

For another example, each of the light emitting elements may include a quantum dot light emitting diode including a quantum dot light emitting layer, an inorganic light emitting diode including an inorganic semiconductor, or a micro light emitting diode.

The encapsulation layer TFEL may cover upper and side surfaces of the light emitting element layer EML and may protect the light emitting element layer EML. The encapsulation layer TFEL may include at least one inorganic layer and at least one organic layer to encapsulate the light emitting element layer EML.

The touch sensing unit TSU may be disposed on the encapsulation layer TFEL. The touch sensing unit TSU may include a plurality of touch electrodes for sensing a user's touch in a capacitive manner and touch lines connecting the touch electrodes and the touch driver 400. For example, the touch sensing unit TSU may sense a user's touch in a mutual capacitance manner or a self-capacitance manner.

For another example, the touch sensing unit TSU may be disposed on a separate substrate disposed on the display unit DU. In this case, the substrate supporting the touch sensing unit TSU may be an encapsulation substrate that encapsulates the display unit DU.

The touch electrodes of the touch sensing unit TSU may be disposed in a touch sensor area overlapping the display area DA. The touch lines of the touch sensing unit TSU may be disposed in a touch peripheral area overlapping the non-display area NDA.

The color filter layer CFL may be disposed on the touch sensing unit TSU. The color filter layer CFL may include a plurality of color filters disposed in areas corresponding to a plurality of emission areas, respectively. Each of the color filters may selectively transmit light of a specific wavelength and block or absorb light of other wavelengths. The color filter layer CFL may absorb a part of light coming from the outside of the display device 10, thereby reducing reflected light caused by the external light. Therefore, the color filter layer CFL can prevent color distortion caused by reflection of external light.

Since the color filter layer CFL is directly disposed on the touch sensing unit TSU, the display device 10 may not require a separate substrate for the color filter layer CFL. Therefore, a thickness of the display device 10 can be relatively reduced.

The sub-area SBA of the display panel 100 may extend from a side of the main area MA. The sub-area SBA may include a flexible material that can be bent, folded, rolled, etc. For example, when the sub-area SBA is bent, it may be overlapped with the main area MA in the thickness direction (Z-axis direction). The sub-area SBA may include the display driver 200 and the pad unit electrically connected to the circuit board 300.

The display device 10 may include a bending protection layer BPL which protects the sub-area SBA. The bending protection layer BPL may be disposed on the transistor layer TFTL of the bent sub-area SBA. The bending protection layer BPL may protect the transistor layer TFTL of the bent sub-area SBA and minimize tensile stress of the sub-area SBA.

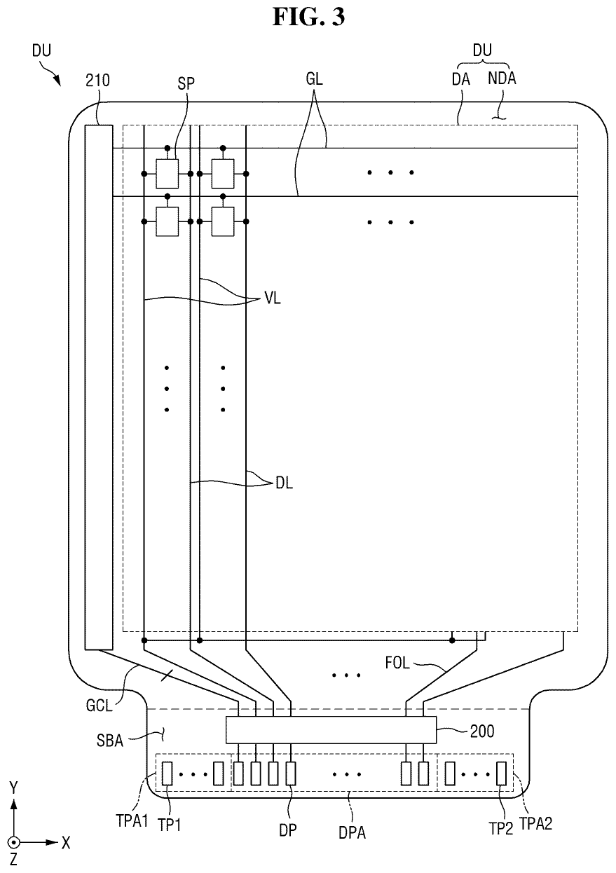

FIG. 3 is a plan view of the display unit DU of the display device 10 according to the embodiment.

Referring to FIG. 3, the display unit DU may include the display area DA and the non-display area NDA.

The display area DA is an area for displaying an image and may be defined as a central area of the display panel 100. The display area DA may include a plurality of pixels SP, a plurality of gate lines GL, a plurality of data lines DL, and a plurality of power lines VL. Each of the pixels SP may be defined as a minimum unit that outputs light.

The gate lines GL may supply gate signals received from a gate driver 210 to the pixels SP. The gate lines GL may extend in the X-axis direction and may be spaced apart from each other in the Y-axis direction intersecting the X-axis direction.

The data lines DL may supply data voltages received from the display driver 200 to the pixels SP. The data lines DL may extend in the Y-axis direction and may be spaced apart from each other in the X-axis direction.

The power lines VL may supply a power supply voltage received from the display driver 200 to the pixels SP. Here, the power supply voltage may be at least one of a driving voltage, an initialization voltage, a reference voltage, a bias voltage, and a low potential voltage. The power lines VL may extend in the Y-axis direction and may be spaced apart from each other in the X-axis direction.

The non-display area NDA may surround the display area DA. The non-display area NDA may include the gate driver 210, fan-out lines FOL, and gate control lines GCL. The gate driver 210 may generate a plurality of gate signals based on a gate control signal and sequentially supply the gate signals to the gate lines CL according to a set order.

The fan-out lines FOL may extend from the display driver 200 to the display area DA. The fan-out lines FOL may supply data voltages received from the display driver 200 to the data lines DL.

The gate control lines GCL may extend from the display driver 200 to the gate driver 210. The gate control lines GCL may supply a gate control signal received from the display driver 200 to the gate driver 210.

The sub-area SBA may include a display driver area in which the display driver 200 is disposed, a display pad area DPA, and first and second touch pad areas TPA1 and TPA2.

The display driver 200 may output signals and voltages for driving the display panel 100 to the fan-out lines FOL. The display driver 200 may supply data voltages to the data lines DL through the fan-out lines FOL. The data voltages may be supplied to the pixels SP and may determine luminances of the pixels SP. The display driver 200 may supply a gate control signal to the gate driver 210 through the gate control lines GCL.

The display pad area DPA, the first touch pad area TPA1, and the second touch pad area TPA2 may be disposed at an edge of the sub-area SBA. Pad units in the display pad area DPA, the first touch pad area TPA1, and the second touch pad area TPA2 may be electrically connected to the circuit board 300 using a low-resistance high-reliability material such as an anisotropic conductive film or self-assembly anisotropic conductive paste (SAP).

The display pad area DRA may include a plurality of display pad units DP. The display pad units DP may be electrically connected to a graphics system through the circuit board 300. The display pad units DP may be connected to the circuit board 300 to receive digital video data and may supply the digital video data to the display driver 200.

The first touch pad area TPA1 may be disposed on a side of the display pad area DPA and may include a plurality of first touch pad units TP1. The first touch pad units TP1 may be electrically connected to the touch driver 400 disposed on the circuit board 300. The first touch pad units TP1 may supply touch driving signals to a plurality of driving electrodes through a plurality of driving lines.

The second touch pad area TPA2 may be disposed on the other side of the display pad area DPA and may include a plurality of second touch pad units TP2. The second touch pad units TP2 may be electrically connected to the touch driver 400 disposed on the circuit board 300. The touch driver 400 may receive touch sensing signals through a plurality of sensing lines connected to the second touch pad units TP2 and sense a change in mutual capacitance between the driving electrodes and sensing electrodes.

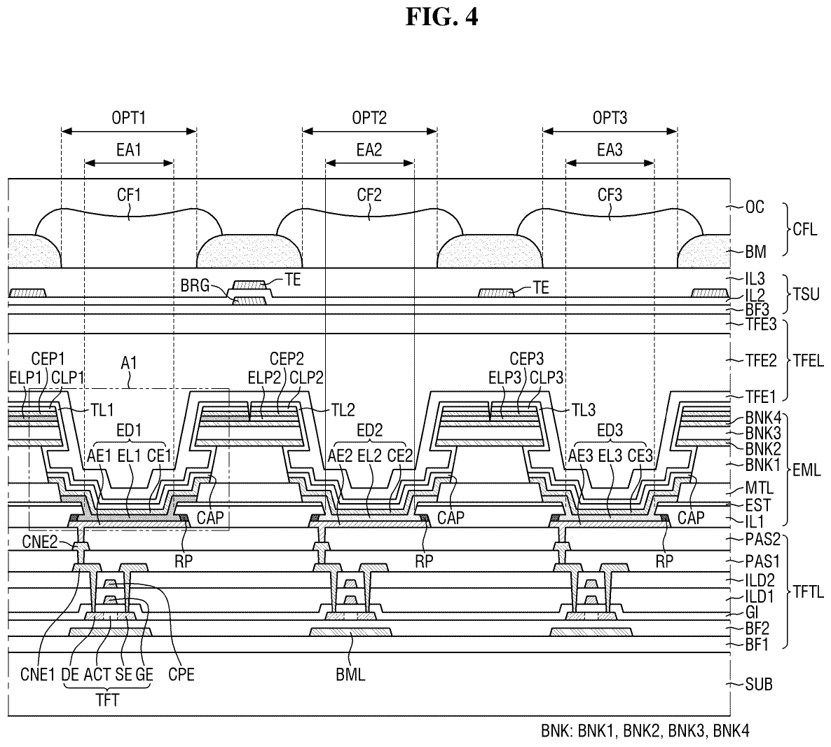

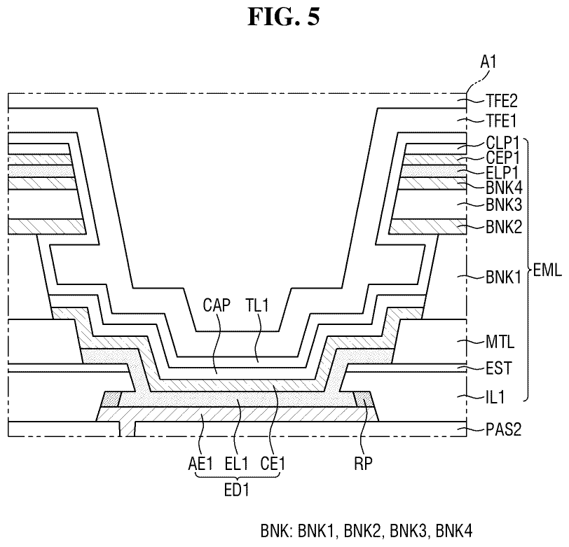

FIG. 4 is a cross-sectional view illustrating pixels of the display device 10 according to the embodiment. FIG. 5 is an enlarged view of area A1 of FIG. 4.

Referring to FIGS. 4 and 5, the display panel 100 may include the display unit DU, the touch sensing unit TSU, and the color filter layer CFL. The display unit DU may include the substrate SUB, the thin-film transistor layer TFTL, the light emitting element layer EML, and the encapsulation layer TFEL.

The substrate SUB may be a base substrate or a base member. The substrate SUB may be a flexible substrate that can be bent, folded, rolled, etc. For example, the substrate SUB may include polymer resin such as polyimide (PI), but the present disclosure is not limited thereto. For another example, the substrate SUB may include a glass material or a metal material.

The thin-film transistor layer TFTL may include a first buffer layer BF1, light blocking layers BML, a second buffer layer BF2, thin-film transistors TFT, a gate insulating layer GI, a first interlayer insulating layer ILD1, capacitor electrodes CPE, a second interlayer insulating layer ILD2, first connection electrodes CNE1, a first passivation layer PAS1, second connection electrodes CNE2, and a second passivation layer PAS2.

The first buffer layer BF1 may be disposed on the substrate SUB. The first buffer layer BFI may include an inorganic layer that can prevent penetration of air or moisture. For example, the first buffer layer BIF may include a plurality of inorganic layers stacked alternately.

The light blocking layers BML may be disposed on the first buffer layer BF1. For example, each of the light blocking layers BML may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof. For another example, each of the light blocking layers BML may be an organic layer including a black pigment.

The second buffer layer BF2 may be disposed on the first buffer layer BF1 and the light blocking layers BML. The second buffer layer BF2 may include an inorganic layer that can prevent penetration of air or moisture. For example, the second buffer layer BF2 may include a plurality of inorganic layers stacked alternately.

The thin-film transistors TFT may be disposed on the second buffer layer BF2 and may constitute pixel circuits of pixels. For example, each of the thin-film transistors TFT may be a driving transistor or a switching transistor of a pixel circuit. Each of the thin-film transistors TFT may include a semiconductor region ACT, a source electrode SE, a drain electrode DE, and a gate electrode GE.

The semiconductor region ACT, the source electrode SE, and the drain electrode DE may be disposed on the second buffer layer BF2. The semiconductor region ACT, the source electrode SE, and the drain electrode DE may overlap a light blocking layer BML in the thickness direction. The semiconductor region ACT may be overlapped with the gate electrode GE in the thickness direction and may be insulated from the gate electrode GE by the gate insulating layer GI. The source electrode SE and the drain electrode DE may be formed by making the material of the semiconductor region ACT conductive.

The gate electrode GE may be disposed on the gate insulating layer GI. The gate electrode GE may overlap the semiconductor region ACT with the gate insulating layer GI interposed between them.

The gate insulating layer GI may be disposed on the semiconductor regions ACT, the source electrodes SE, the drain electrodes DE, and the second buffer layer BF2. The gate insulating layer GI may insulate the semiconductor regions ACT from the gate electrodes GE.

The first interlayer insulating layer ILD1 may be disposed on the gate electrodes GE and the gate insulating layer GI. The first interlayer insulating layer ILD1 may insulate the gate electrodes GE from the capacitor electrodes CPE.

The capacitor electrodes CPE may be disposed on the first interlayer insulating layer ILD1 The capacitor electrodes CPE may overlap the gate electrodes GE in the thickness direction. The capacitor electrodes CPE and the gate electrodes GE may form capacitances.

The second interlayer insulating layer ILD2 may be disposed on the capacitor electrodes CPE and the first interlayer insulating layer ILD1. The second interlayer insulating layer ILD2 may insulate the capacitor electrodes CPE from the first connection electrodes CNE1.

The first connection electrodes CNE1 may be disposed on the second interlayer insulating layer ILD2. The first connection electrodes CNE1 may electrically connect the drain electrodes DE of the thin-film transistors TFT to the second connection electrodes CNE2. The first connection electrodes CNE1 may be formed in contact holes provided in the second interlayer insulating layer ILD2, the first interlayer insulating layer ILD1 and the gate insulating layer GI to contact the drain electrodes DE of the thin-film transistors TET.

The first passivation layer PAS1 may be disposed on the first connection electrodes CNE1 and the second interlayer insulating layer ILD2. The first passivation layer PAS1 may protect the thin-film transistors TFT. The first passivation layer PAS1 may insulate the first connection electrodes CNE1 and the second connection electrodes CNE2.

The second connection electrodes CNE2 may be disposed on the first passivation layer PAS1. A second connection electrode CNE2 may electrically connect a first connection electrode CNE1 to a first pixel electrode AE1 of a first light emitting element ED1. The second connection electrodes CNE2 may be formed in contact holes provided in the first passivation layer PAS1 to contact the first connection electrodes CNE1.

The second passivation layer PAS2 may be disposed on the second connection electrodes CNE2 and the first passivation layer PAS1. The second passivation layer PAS2 may insulate the second connection electrodes CNE2 and the first pixel electrode AE1.

The light emitting element layer EML may be disposed on the thin-film transistor layer TFTL. The light emitting element layer EML may include first through third light emitting elements ED1 through ED3, residual patterns RP, a first insulating layer TL1, an etch control layer EST, capping layers CAP, a conductive layer MTL, a bank BNK, first through third organic patterns ELP1 through ELP3, first through third electrode patterns CEP1 through CEP3, first through third capping patterns CLP1 through CLP3, and first through third inorganic layers TL1 through TL3.

The display device 10 may include a plurality of pixels arranged along a plurality of rows and a plurality of columns in the display area DA. The pixels may respectively include first through third emission areas EA1 through EA3 defined by the bank BNK or the pixel defining layer and may emit light having a predetermined peak wavelength through the first through third emission areas EA1 through EA3. Each of the first through third emission areas EA1 through EA3 may be areas through which light generated by light emitting elements of the display device 10 is emitted to the outside of the display device 10.

Each of the first through third emission areas EA1 through EA3 may emit light having a predetermined peak wavelength to the outside of the display device 10. The first emission area EA1 may emit light of a first color, the second emission area EA2 may emit light of a second color, and the third emission area EA3 may emit light of a third color. For example, the light of the first color may be red light having a peak wavelength of about 610 to 650 nm, the light of the second color may be green light having a peak wavelength of about 510 to 550 nm, and the light of the third color may be blue light having a peak wavelength of about 440 to 480 nm. However, the present disclosure is not limited thereto.

For example, the area of the third emission area EA3 may be larger than the area of the first emission area EA1, and the area of the first emission area EA1 may be larger than the area of the second emission area EA2. However, the present disclosure is not limited thereto. For another example, the area of the first emission area EA1, the area of the second emission area EA2, and the area of the third emission area EA3 may be substantially the same.

The first light emitting element ED1 may be disposed on the thin-film transistor layer TFTL in the first emission area EA1. The first light emitting element ED1 may include the first pixel electrode AE1, a first light emitting layer EL1, and a first common electrode CE1. The second light emitting element ED2 may be disposed on the thin-film transistor layer TFTL in the second emission area EA2. The second light emitting element ED2 may include a second pixel electrode AE2, a second light emitting layer EL2, and a second common electrode CE2. The third light emitting element ED3 may be disposed on the thin-film transistor layer TFTL in the third emission area EA3. The third light emitting element ED3 may include a third pixel electrode AE3, a third light emitting layer EL3, and a third common electrode CE3.

The first through third pixel electrodes AE1 through AE3 may be disposed on the second passivation layer PAS2. Each of the first through third pixel electrodes AE1 through AE3 may be electrically connected to the drain electrode DE of a thin-film transistor TFT through the first and second connection electrodes CNE1 and CNE2. The first through third pixel electrodes AE1 through AE3 may be insulated from each other by the first insulating layer ILL. For example, the first through third pixel electrodes AE1 through AE3 may include at least one of silver (Ag), copper (Cu), aluminum (Al), nickel (Ni), and lanthanum (La). For another example, the first through third pixel electrodes AE1 through AE3 may include a material such as indium tin oxide (ITO), indium zinc oxide (IZO), or indium tin zinc oxide (ITZO). For another example, the first through third pixel electrodes AE1 through AE3 may have a stacked structure of ITO/Ag/ITO, ITO/Ag/IZO, or ITO/Ag/ITZO/IZO.

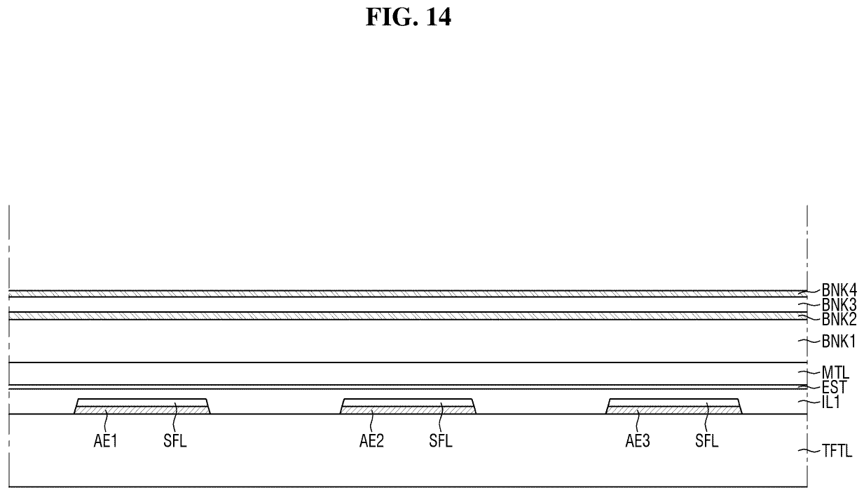

Residual patterns RP may be disposed on edges of each of the first through third pixel electrodes AE1 through AE3. The first insulating layer IL1 may not directly contact an upper surface of each of the first through third pixel electrodes AE1 through AE3 due to the residual patterns RP. The residual patterns RP may be formed as a result of removing a sacrificial layer SFL (see FIG. 14) on each of the first through third pixel electrodes AE1 through AE3 in a process of manufacturing the display device 10.

The first insulating layer IL1 may be disposed on the second passivation layer PAS2 and the residual patterns RP. The first insulating layer IL1 may be disposed on the edges of the first through third pixel electrodes AE1 through AE3 and the residual patterns RP, and may be patterned to partially expose the upper surfaces of the first through third pixel electrodes AE1 through AE3 in a process forming the first insulating layer ILL. For example, the first insulating layer IL1 may expose the first pixel electrode AE1 in the first emission area EA1, and the first light emitting layer EL1 may be directly disposed on the first pixel electrode AE1. The first insulating layer IL1 may include an inorganic insulating material. The first insulating layer IL1 may include, but is not limited to, at least one of a silicon nitride layer, a silicon oxynitride layer, a silicon oxide layer, a titanium oxide layer, an aluminum oxide layer, and an amorphous silicon layer.

The etch control layer EST may be disposed on the first insulating layer IL1. The etch control layer EST may function as an etching stopper. The etch control layer EST may protect the first through third pixel electrodes AE1 through AE3 during a process of etching the bank BNK and the conductive layer MTL. Optionally, the etch control layer EST may be omitted.

The first through third light emitting layers ELI through EL3 may be organic light emitting layers made of an organic material and may be formed on the first through third pixel electrodes AE1 through AE3 through a deposition process. For example, an organic material may be deposited in a direction inclined from an upper surface of the substrate SUB in a deposition process of the first through third light emitting layers EL1 through EL3.

The first light emitting layer ELI may be directly disposed on the first pixel electrode AE1 in the first emission area EA1. A portion of the first light emitting layer EL1 may fill a space surrounded by the first pixel electrode AE1, the residual patterns RP and the first insulating layer IL1, and another portion of the first light emitting layer EL1 may cover upper surfaces of the etch control layer EST and side surfaces of the first insulating layer IL1 and the etch control layer EST. The second light emitting layer EL2 may be directly disposed on the second pixel electrode AE2 in the second emission area EA2. A portion of the second light emitting layer EL2 may fill a space surrounded by the second pixel electrode AE2, the residual patterns RP and the first insulating layer IL1, and another portion of the second light emitting layer EL2 may cover the upper surfaces of the etch control layer EST and the side surfaces of the first insulating layer IL1 and the etch control layer EST. The third light emitting layer EL3 may be directly disposed on the third pixel electrode AE3 in the third emission area EA3. A portion of the third light emitting layer EL3 may fill a space surrounded by the third pixel electrode AE3, the residual patterns RP and the first insulating layer IL1, and another portion of the third light emitting layer EL3 may cover the upper surfaces of the etch control layer EST and the side surfaces of the first insulating layer IL1 and the etch control layer EST.

The first common electrode CE1 may be disposed on the first light emitting layer EL1, the second common electrode CE2 may be disposed on the second light emitting layer EL2, and the third common electrode CE3 may be disposed on the third light emitting layer EL3. The first through third common electrodes CE1 through CE3 may include a transparent conductive material and transmit light generated from the first through third light emitting layers EL1 through EL3. The first through third common electrodes CE1 through CE3 may contact side surfaces of the conductive layer MTL and upper surfaces of the conductive layer MTL. The first through third common electrodes CE1 through CE3 may be electrically connected by the conductive layer MTL. For example, the first common electrode CE1 may receive a common voltage, a cathode voltage, or a low potential voltage.

The first pixel electrode AE1 may receive a voltage corresponding to a data voltage from a thin-film transistor TFT, and the first common electrode CE1 may receive a common voltage, a cathode voltage or a low potential voltage. In this case, since a potential difference is formed between the first pixel electrode AE1 and the first common electrode CE1, holes may move to the first light emitting layer EL1 through a hole transporting layer, and electrons may move to the first light emitting layer ELI through an electron transporting layer. Accordingly, the first light emitting layer EL1 may emit light.

The capping layers CAP may be disposed on the first through third common electrodes CE1 through CE3 in the first through third emission areas EA1 through EA3. The capping layers CAP may include an inorganic insulating material and may cover the first through third light emitting elements ED1 through ED3. The capping layers CAP may prevent the first through third light emitting elements ED1 through ED3 from being damaged by external air. For example, the capping layers CAP may include, but are not limited to, at least one of a silicon nitride layer, a silicon oxynitride layer, a silicon oxide layer, a titanium oxide layer, an aluminum oxide layer, and an amorphous silicon layer.

The conductive layer MTL may be disposed on the etch control layer EST to be overlapped with the bank BNK. The conductive layer MTL may surround the first through third emission areas EA1 through EA3 in a plan view. The conductive layer MTL may include a metal material with high electrical conductivity. For example, the conductive layer MTL may include, but is not limited to, aluminum (Al). The first through third common electrodes CE1 through CE3 may be electrically connected to the conductive layer MTL.

The bank BNK may be disposed on the conductive layer MTL to define the first through third emission areas EA1 through EA3. The bank BNK may surround the first through third emission areas EA1 through EA3 in a plan view. The bank BNK may include first through fourth banks BNK1 through BNK4.

The first bank BNK1 may be disposed on the conductive layer MTL, the second bank BNK2 may be disposed on the first bank BNK1, the third bank BNK3 may be disposed on the second bank BNK2, and the fourth bank BNK4 may be disposed on the third bank BNK3. Side surfaces of the first bank BNK1 may be recessed inward from side surfaces of the second through fourth banks BNK2 through BNK4. Since the side surfaces of the second bank BNK2 protrude from the side surfaces of the first bank BNK1 toward the first emission area EA1, the second bank BNK2 may include protruding tips. Accordingly, an undercut structure may be formed under each tip of the second bank BNK2. A thickness of the first bank BNK1 may be greater than the sum of thicknesses of the second through fourth banks BNK2 through BNK4. The thickness of the third bank BNK3 may be greater than the thickness of each of the second and fourth banks BNK2 and BNK4.

The first and second banks BNK1 and BNK2 may include different metal materials. An etching rate of the first bank BNK1 and an etching rate of the second bank BNK2 may be different from each other. For example, the etching rate of the first bank BNK1 may be higher than that of the second bank BNK2 in a wet etching process, and the first bank BNK1 may be etched more than the second bank BNK2 in the process of forming the first through third emission areas EA1 through EA3. Therefore, a profile of the first and second banks BNK1 and BNK2 may be determined by a difference in etching rate between the first and second banks BNK1 and BNK2. The first bank BNK1 may include a metal material having high electrical conductivity, and the second bank BNK2 may include a material having low reflectivity. For example, the first bank BNK1 may include aluminum (Al), and the second bank BNK2 may include titanium (Ti). However, the present disclosure is not limited thereto.

The third bank BNK3 may include an inorganic insulating material. The third bank BNK3 may include, but is not limited to, at least one of a silicon nitride layer, a silicon oxynitride layer, a silicon oxide layer, a titanium oxide layer, an aluminum oxide layer, and an amorphous silicon layer. The fourth bank BNK4 may include a metal material. The fourth bank BNK4 may include one of molybdenum (Mo), aluminum (Al), chromium (Cr), gold (Au), titanium (Ti), nickel (Ni), neodymium (Nd), and copper (Cu).

Since the display device 10 includes the third bank BNK3 including an inorganic insulating material and the fourth bank BNK4 including a metal material, a contact area between each of the first through third inorganic layers TL1 through TL3 and the bank BNK may increase. It is difficult to increase horizontal area of the bank BNK to secure the contact area between each of the first through third inorganic layers TL1 through TL3 and the bank BNK. By additionally forming the third and fourth banks BNK3 and BNK4 on the second bank BNK2, the contact area between each of the first through third inorganic layers TL1 through TL3 and the bank BNK may increase, thereby effectively blocking a moisture penetration path. As a result, the reliability of the first through third light emitting elements ED1 through ED3 can be improved. In addition, the third bank BNK3 may maximize an encapsulation effect by including the same inorganic insulating material as the first through third inorganic layers TL1 through TL3.

The bank BNK may form the first through third emission areas EA1 through EA3 through a mask process, and the first through third light emitting layers EL1 through EL3 may be formed in the first through third emission areas EA1 through EA3, respectively. When a mask process is performed, a structure for supporting a mask may be required, and an excessively wide non-display area NDA may be required to control dispersion of the mask process. Therefore, if the mask process is minimized, a structure for supporting a mask can be omitted, and the area of the non-display area NDA for dispersion control can be minimized.

The first through third light emitting elements ED1 through ED3 may be formed through deposition and etching processes rather than a mask process. Since the first and second banks BNK1 and BNK2 include different metal materials, each inner wall of the bank BNK may have a tip structure. In the display device 10, different layers may be individually formed in the first through third emission areas EA1 through EA3 through a deposition process. For example, the first light emitting layer ELI and the first organic pattern ELP1 may be deposited using the same organic material in a deposition process without a mask and may be disconnected due to the tips formed on the inner walls of the bank BNK. The first light emitting layer ELI may be disposed in the first emission area EA1, and the first organic pattern ELP1 may be disposed on the bank BNK disposed adjacent to the first emission area EA1.

An organic material for forming the first light emitting layer ELI may be deposited on the entire surface of the display device 10, and the organic material of the first light emitting layer ELI deposited in the second and third emission areas EA2 and EA3 may be removed. An organic material for forming the second light emitting layer EL2 may be deposited on the entire surface of the display device 10, and the organic material of the second light emitting layer EL2 deposited in the first and third emission areas EA1 and EA3 may be removed. An organic material for forming the third light emitting layer EL3 may be deposited on the entire surface of the display device 10, and the organic material of the third light emitting layer EL3 deposited in the first and second emission areas EA1 and EA2 may be removed. Therefore, in the display device 10, different organic materials can be formed in the first through third emission areas EA1 through EA3 through deposition and etching processes without using a mask process. The display device 10 can reduce manufacturing costs by omitting unnecessary processes and can minimize the area of the non-display area NDA.

The first organic pattern ELP1 may include the same organic material as the first light emitting layer EL1. The first organic pattern ELP1 may be disposed on the fourth bank BNK4 disposed adjacent to the first emission area EA1. The first light emitting layer EL1 and the first organic pattern ELP1 may be deposited in the same process and may be disconnected due to tips of the second bank BNK2. Accordingly, the first organic pattern ELP1 may be disposed on the fourth bank BNK4 in an area disposed adjacent to the first emission area EA1.

The first electrode pattern CEP1 may include the same metal material as the first common electrode CE1 and may be disposed on the first organic pattern ELP1. The first common electrode CE1 and the first electrode pattern CEP1 may be deposited in the same process and may be disconnected due to the tips of the second bank BNK2. Accordingly, the first electrode pattern CEP1 may be disposed on the first organic pattern ELP1 in the area disposed adjacent to the first emission area EA1.

The first capping pattern CLP1 may include the same inorganic material as the capping layer CAP and may be disposed on the first electrode pattern CEP1. The capping layer CAP and the first capping pattern CLP1 may be deposited in the same process and may be disconnected due to the tips of the second bank BNK2. Accordingly, the first capping pattern CLP1 may be disposed on the first electrode pattern CEP1 in the area disposed adjacent to the first emission area EA1.

The first inorganic layer TL1 may be disposed on the capping layer CAP of the first emission area EA1 and the first capping pattern CLP1. The first inorganic layer TL1 may cover an upper surface of the capping layer CAP in the first emission area EA1. The first inorganic layer TL1 may cover the side surfaces of the first bank BNK1, lower and side surfaces of the tips of the second bank BNK2, the side surfaces of the third and fourth banks BNK3 and BNK4, side surfaces of the first organic pattern ELP1, side surfaces of the first electrode pattern CEP1, and upper and side surfaces of the first capping pattern CLP1. The first inorganic layer TL1 may include an inorganic material to prevent oxygen or moisture from penetrating into the first light emitting element ED1. The first inorganic layer TL1 may be an inorganic encapsulation layer. For example, the first inorganic layer TL1 may include, but is not limited to, at least one of a silicon nitride layer, a silicon oxynitride layer, a silicon oxide layer, a titanium oxide layer, an aluminum oxide layer, and an amorphous silicon layer.

The second organic pattern ELP2 may include the same organic material as the second light emitting layer EL2. The second organic pattern ELP2 may be disposed on the fourth bank BNK4 disposed adjacent to the second emission area EA2. The second light emitting layer EL2 and the second organic pattern ELP2 may be deposited in the same process and may be disconnected due to tips of the second bank BNK2. Accordingly, the second organic pattern ELP2 may be disposed on the fourth bank BNK4 in an area disposed adjacent to the second emission area EA2.

The second electrode pattern CEP2 may include the same metal material as the second common electrode CE2 and may be disposed on the second organic pattern ELP2. The second common electrode CE2 and the second electrode pattern CEP2 may be deposited in the same process and may be disconnected due to the tips of the second bank BNK2. Accordingly, the second electrode pattern CEP2 may be disposed on the second organic pattern ELP2 in the area disposed adjacent to the second emission area EA2.

The second capping pattern CLP2 may include the same inorganic material as the capping layer CAP and may be disposed on the second electrode pattern CEP2. The capping layer CAP and the second capping pattern CLP2 may be deposited in the same process and may be disconnected due to the tips of the second bank BNK2. Accordingly, the second capping pattern CLP2 may be disposed on the second electrode pattern CEP2 in the area disposed adjacent to the second emission area EA2.

The second inorganic layer TL2 may be disposed on the capping layer CAP of the second emission area EA2 and the second capping pattern CLP2. The second inorganic layer TL2 may cover an upper surface of the capping layer CAP in the second emission area EA2. The second inorganic layer TL2 may cover the side surfaces of the first bank BNK1, the lower and side surfaces of the tips of the second bank BNK2, the side surfaces of the third and fourth banks BNK3 and BNK4, side surfaces of the second organic pattern ELP2, side surfaces of the second electrode pattern CEP2, and upper and side surfaces of the second capping pattern CLP2. The second inorganic layer TL2 may include an inorganic material to prevent oxygen or moisture from penetrating into the second light emitting element ED2. The second inorganic layer TL2 may be an inorganic encapsulation layer. For example, the second inorganic layer TL2 may be made of at least one of the materials exemplified in the description of the first inorganic layer TL1.

The third organic pattern ELP3 may include the same organic material as the third light emitting layer EL3. The third organic pattern ELP3 may be disposed on the fourth bank BNK4 disposed adjacent to the third emission area EA3. The third light emitting layer EL3 and the third organic pattern ELP3 may be deposited in the same process and may be disconnected due to tips of the second bank BNK2. Accordingly, the third organic pattern ELP3 may be disposed on the fourth bank BNK4 in an area disposed adjacent to the third emission area EA3.

The third electrode pattern CEP3 may include the same metal material as the third common electrode CE3 and may be disposed on the third organic pattern ELP3. The third common electrode CE3 and the third electrode pattern CEP3 may be deposited in the same process and may be disconnected due to the tips of the second bank BNK2. Accordingly, the third electrode pattern CEP3 may be disposed on the third organic pattern ELP3 in the area disposed adjacent to the third emission area EA3.

The third capping pattern CLP3 may include the same inorganic material as the capping layer CAP and may be disposed on the third electrode pattern CEP3. The capping layer CAP and the third capping pattern CLP3 may be deposited in the same process and may be disconnected due to the tips of the second bank BNK2. Accordingly, the third capping pattern CLP3 may be disposed on the third electrode pattern CEP3 in the area disposed adjacent to the third emission area EA3.

The third inorganic layer TL3 may be disposed on the capping layer CAP of the third emission area EA3 and the third capping pattern CLP3. The third inorganic layer TL3 may cover an upper surface of the capping layer CAP in the third emission area EA3. The third inorganic layer TL3 may cover the side surfaces of the first bank BNK1, the lower and side surfaces of the tips of the second bank BNK2, the side surfaces of the third and fourth banks BNK3 and BNK4, side surfaces of the third organic pattern ELP3, side surfaces of the third electrode pattern CEP3, and upper and side surfaces of the third capping pattern CLP3. The third inorganic layer TL3 may include an inorganic material to prevent oxygen or moisture from penetrating into the third light emitting element ED3. The third inorganic layer TL3 may be an inorganic encapsulation layer. For example, the third inorganic layer TL3 may be made of at least one of the materials exemplified in the description of the first inorganic layer TL1.

The encapsulation layer TFEL may be disposed on the first through third inorganic layers TL1 through TL3 to cover the light emitting element layer EML. The encapsulation layer TFEL may include first through third encapsulation layers TFE1 through TFE3.

The first encapsulation layer TFE1 may be disposed on the first through third inorganic layers TL1 through TL3. The first encapsulation layer TFE1 may include an inorganic material to prevent oxygen or moisture from penetrating into the light emitting element layer EML. For example, the first encapsulation layer TFE1 may include, but is not limited to, at least one of a silicon nitride layer, a silicon oxynitride layer, a silicon oxide layer, a titanium oxide layer, an aluminum oxide layer, and an amorphous silicon layer.

The second encapsulation layer TFE2 may be disposed on the first encapsulation layer TFE1 to planarize the top of the light emitting element layer EML. The second encapsulation layer TFE2 may include an organic material to protect the light emitting element layer EML from foreign substances such as dust. For example, the second encapsulation layer TFE2 may include an organic layer such as acryl resin, epoxy resin, phenolic resin, polyamide resin, or polyimide resin. The second encapsulation layer TFE2 may be formed by curing a monomer or applying a polymer.

The third encapsulation layer TFE3 may be disposed on the second encapsulation layer TFE2. The third encapsulation layer TFE3 may include an inorganic material to prevent oxygen or moisture from penetrating into the light emitting element layer EML. For example, the third encapsulation layer TFE3 may be made of at least one of the materials exemplified in the description of the first encapsulation layer TFE1.

The touch sensing unit TSU may be disposed on the encapsulation layer TFEL. The touch sensing unit TSU may include a third buffer layer BF3, a bridge electrode BRG, a second insulating layer IL2, touch electrodes TE, and a third insulating layer IL3.

The third buffer layer BF3 may be disposed on the encapsulation layer TFEL. The third buffer layer BF3 may have insulating and optical functions. The third buffer layer BF3 may include at least one inorganic layer. Optionally, the third buffer layer BF3 may be omitted.

The bridge electrode BRG may be disposed on the third buffer layer BF3. The bridge electrode BRG may be disposed on a different layer from the touch electrodes TE and may electrically connect adjacent touch electrodes TE.

The second insulating layer IL2 may be disposed on the bridge electrode BRG and the third buffer layer BF3. The second insulating layer IL2 may have insulating and optical functions. For example, the second insulating layer IL2 may include, but is not limited to, at least one of a silicon nitride layer, a silicon oxynitride layer, a silicon oxide layer, a titanium oxide layer, an aluminum oxide layer, and an amorphous silicon layer.

The touch electrodes TE may be disposed on the second insulating layer IL2. The touch electrodes TE may include driving electrodes and sensing electrodes and sense a change in mutual capacitance between the driving electrodes and the sensing electrodes. The touch electrodes TE may not overlap the first through third emission areas EA1 through EA3. Each of the touch electrodes TE may be a single layer of molybdenum (Mo), titanium (Ti), copper (Cu), aluminum (Al) or indium tin oxide (ITO) or may be a stacked structure of aluminum and titanium (Ti/Al/Ti), a stacked structure of aluminum and indium tin oxide (ITO/Al/ITO), an APC alloy, or a stacked structure of an APC alloy and indium tin oxide (ITO/APC/ITO).

The third insulating layer IL3 may be disposed on the touch electrodes TE and the second insulating layer IL2. The third insulating layer IL3 may have insulating and optical functions. The third insulating layer IL3 may be made of at least one of the materials exemplified in the description of the second insulating layer IL2.

The color filter layer CFL may be disposed on the touch sensing unit TSU. The color filter layer CFL may include a light blocking member BM, first through third color filters CF1 through CF3, and a planarization layer OC.

The light blocking member BM may be disposed on the third insulating layer IL3 to surround first through third optical areas OPTI through OPT3. The light blocking member BM may overlap the touch electrodes TE. The light blocking member BM may include a light absorbing material to prevent reflection of light. For example, the light blocking member BM may include an inorganic black pigment, an organic black pigment, or an organic blue pigment. The inorganic black pigment may be a metal oxide such as carbon black or titanium black, the organic black pigment may include at least one of lactam black, perylene black and aniline black, and the organic blue pigment may be C.I pigment blue. However, the present disclosure is not limited thereto. The light blocking member BM may prevent color mixing by preventing intrusion of visible light between the first through third emission areas EA1 through EA3, thereby improving a color gamut of the display device 10.

The first through third color filters CF1 through CF3 may be disposed on the third insulating layer IL3 to correspond to the first through third emission areas EA1 through EA3, respectively.

The first color filter CF1 may be disposed on the third insulating layer IL3 in the first emission area EA1. The first color filter CF1 may be surrounded by the light blocking member BM in a plan view. Edges of the first color filter CF1 may partially cover an upper surface of the light blocking member BM, but the present disclosure is not limited thereto. The first color filter CF1 may selectively transmit light of the first color (e.g., red light) and block or absorb light of the second color (e.g., green light) and light of the third color (e.g., blue light). For example, the first color filter CF1 may be a red color filter and may include a red colorant.

The second color filter CF2 may be disposed on the third insulating layer IL3 in the second emission area EA2. The second color filter CF2 may be surrounded by the light blocking member BM in a plan view. Edges of the second color filter CF2 may partially cover the upper surface of the light blocking member BM, but the present disclosure is not limited thereto. The second color filter CF2 may selectively transmit light of the second color (e.g., green light) and block or absorb light of the first color (e.g., red light) and light of the third color (e.g., blue light). For example, the second color filter CF2 may be a green color filter and may include a green colorant.

The third color filter CF3 may be disposed on the third insulating layer IL3 in the third emission area EA3. The third color filter CF3 may be surrounded by the light blocking member BM in a plan view. Edges of the third color filter CF3 may partially cover the upper surface of the light blocking member BM, but the present disclosure is not limited thereto. The third color filter CF3 may selectively transmit light of the third color (e.g., blue light) and block or absorb light of the first color (e.g., red light) and light of the second color (e.g., green light). For example, the third color filter CF3 may be a blue color filter and may include a blue colorant.

The first through third color filters CF1 through CF3 may absorb a part of light coming from the outside of the display device 10, thereby reducing reflected light caused by the external light. Therefore, the first through third color filters CF1 through CF3 can prevent color distortion caused by reflection of external light.

The planarization layer OC may be disposed on the light blocking member BM and the first through third color filters CF1 through CF3. The planarization layer OC may planarize the top surface of the color filter layer CFL. For example, the planarization layer OC may include an organic insulating material.

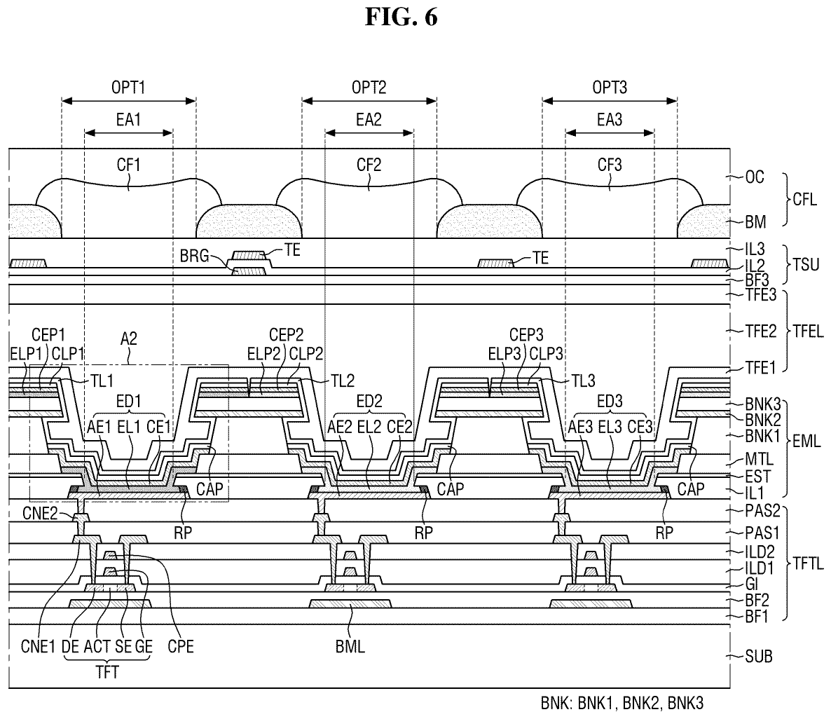

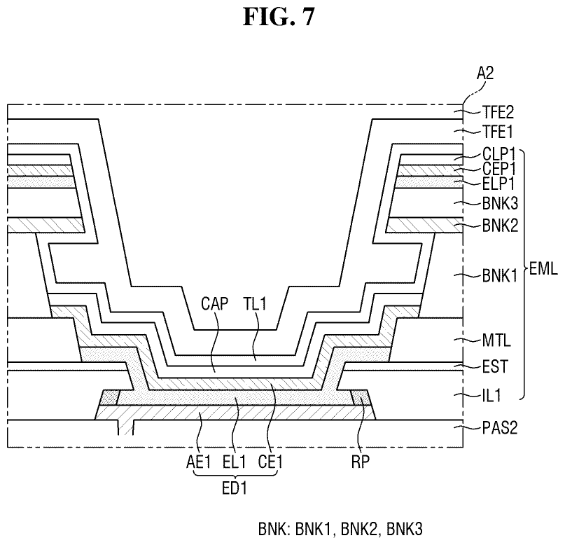

FIG. 6 is a cross-sectional view illustrating pixels of a display device 10 according to an embodiment. FIG. 7 is an enlarged view of area A2 of FIG. 6. The display device 10 of FIGS. 6 and 7 is different from the display device 10 of FIGS. 4 and 5 in the configuration of a bank BNK. The same elements as those described above will be briefly described or will not be described.

Referring to FIGS. 6 and 7, a display panel 100 may include a display unit DU, a touch sensing unit TSU, and a color filter layer CFL. The display unit DU may include a substrate SUB, a thin-film transistor layer TFTL, a light emitting element layer EML, and an encapsulation layer TFEL.

The light emitting element layer EML may be disposed on the thin-film transistor layer TFTL. The light emitting element layer EML may include first through third light emitting elements ED1 through ED3, residual patterns RP, a first insulating layer IL1, an etch control layer EST, capping layers CAP, a conductive layer MTL, the bank BNK, first through third organic patterns ELP1 through ELP3, first through third electrode patterns CEP1 through CEP3, first through third capping patterns CLP1 through CLP3, and first through third inorganic layers TL1 through TL3.

The bank BNK may be disposed on the conductive layer MTL to define first through third emission areas EA1 through EA3. The bank BNK may surround the first through third emission areas EA1 through EA3 in a plan view. The bank BNK may include first through third banks BNK1 through BNK3.

The first bank BNK1 may be disposed on the conductive layer MTL, the second bank BNK2 may be disposed on the first bank BNK1, and the third bank BNK3 may be disposed on the second bank BNK2. Side surfaces of the first bank BNK1 may be recessed inward from side surfaces of the second and third banks BNK2 and BNK3. Since the side surfaces of the second bank BNK2 protrude from the side surfaces of the first bank BNK1 toward the first emission area EA1, the second bank BNK2 may include protruding tips. Accordingly, an undercut structure may be formed under each tip of the second bank BNK2. A thickness of the first bank BNK1 may be greater than the sum of thicknesses of the second and third banks BNK2 and BNK3, and the thickness of the third bank BNK3 may be greater than the thickness of the second bank BNK2.

The first and second banks BNK1 and BNK2 may include different metal materials. An etching rate of the first bank BNK1 and an etching rate of the second bank BNK2 may be different from each other. For example, the etching rate of the first bank BNK1 may be higher than that of the second bank BNK2 in a wet etching process, and the first bank BNK1 may be etched more than the second bank BNK2 in the process of forming the first through third emission areas EA1 through EA3. Therefore, the profile of the first and second banks BNK1 and BNK2 may be determined by a difference in etching rate between the first and second banks BNK1 and BNK2. The first bank BNK1 may include a metal material having high electrical conductivity, and the second bank BNK2 may include a material having low reflectivity. For example, the first bank BNK1 may include aluminum (Al), and the second bank BNK2 may include titanium (Ti). However, the present disclosure is not limited thereto.

For example, the third bank BNK3 may include an inorganic insulating material. The third bank BNK3 may include, but is not limited to, at least one of a silicon nitride layer, a silicon oxynitride layer, a silicon oxide layer, a titanium oxide layer, an aluminum oxide layer, and an amorphous silicon layer.

For another example, the third bank BNK3 may include a metal material. The third bank BNK3 may include one of molybdenum (Mo), aluminum (Al), chromium (Cr), gold (Au), titanium (Ti), nickel (Ni), neodymium (Nd), and copper (Cu).

Since the display device 10 includes the third bank BNK3 including an inorganic insulating material or a metal material, the encapsulation area of each of the first through third inorganic layers TL1 through TL3 can be secured. For example, the horizontal area of the bank BNK may be limited to secure the planar area of each of the first through third emission areas EA1 through EA3. Therefore, the third bank BNK3 may increase the thickness of the bank BNK, and each of the first through third inorganic layers TL1 through TL3 may secure the encapsulation area of the bank BNK, thereby blocking a moisture penetration path. As a result, the reliability of the first through third light emitting elements ED1 through ED3 can be improved. For example, when the third bank BNK3 includes the same inorganic insulating material as the first through third inorganic layers TL1 through TL3, the encapsulation effect of the display device 10 can be maximized.

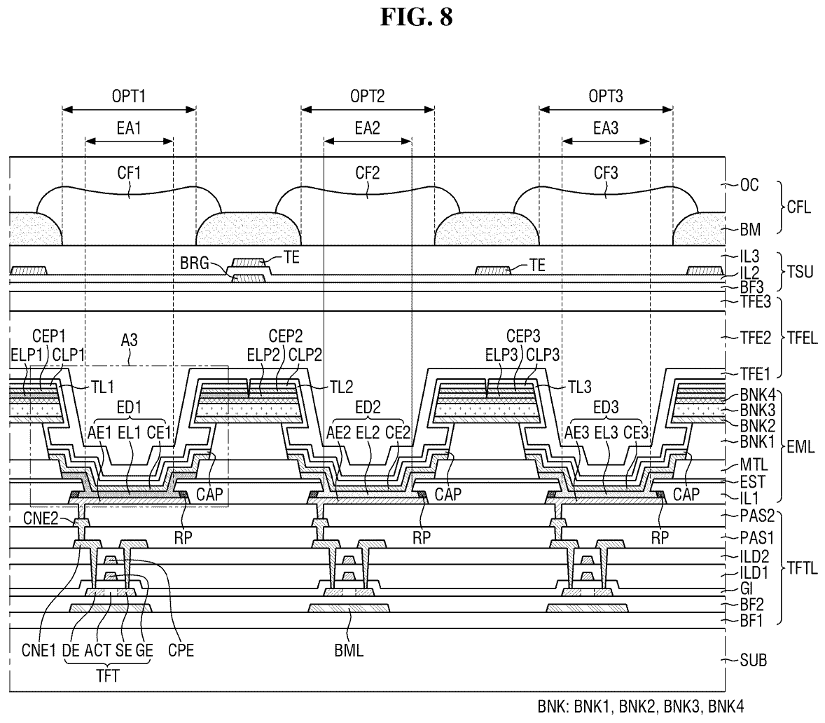

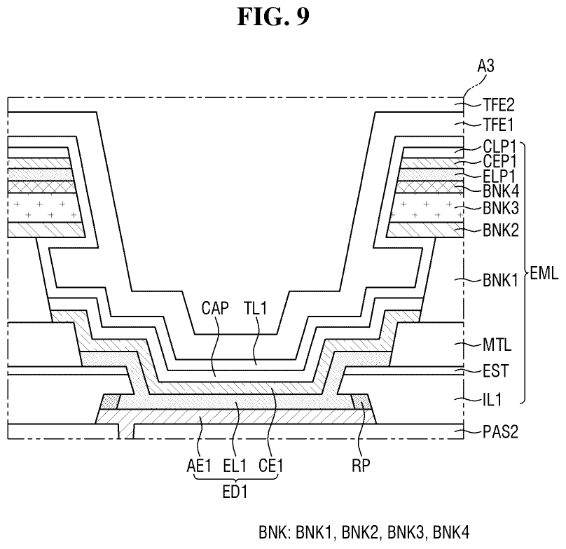

FIG. 8 is a cross-sectional view illustrating pixels of a display device 10 according to an embodiment. FIG. 9 is an enlarged view of area A3 of FIG. 8. The display device 10 of FIGS. 8 and 9 is different from the display device 10 of FIGS. 4 and 5 in the configuration of a bank BNK. The same elements as those described above will be briefly described or will not be described.

Referring to FIGS. 8 and 9, a display panel 100 may include a display unit DU, a touch sensing unit TSU, and a color filter layer CFL. The display unit DU may include a substrate SUB, a thin-film transistor layer TFTL, a light emitting element layer EML, and an encapsulation layer TFEL.

The light emitting element layer EML may be disposed on the thin-film transistor layer TFTL. The light emitting element layer EML may include first through third light emitting elements ED1 through ED3, residual patterns RP, a first insulating layer IL1, an etch control layer EST, capping layers CAP, a conductive layer MTL, the bank BNK, first through third organic patterns ELP1 through ELP3, first through third electrode patterns CEP1 through CEP3, first through third capping patterns CLP1 through CLP3, and first through third inorganic layers TL1 through TL3.

The bank BNK may be disposed on the conductive layer MTL to define first through third emission areas EA1 through EA3. The bank BNK may surround the first through third emission areas EA1 through EA3 in a plan view. The bank BNK may include first through fourth banks BNK1 through BNK4.

The first bank BNK1 may be disposed on the conductive layer MTL, the second bank BNK2 may be disposed on the first bank BNK1, the third bank BNK3 may be disposed on the second bank BNK2, and the fourth bank BNK4 may be disposed on the third bank BNK3. Side surfaces of the first bank BNK1 may be recessed inward from side surfaces of the second through fourth banks BNK2 through BNK4. Since the side surfaces of the second bank BNK2 protrude from the side surfaces of the first bank BNK1 toward the first emission area EA1, the second bank BNK2 may include protruding tips. Accordingly, an undercut structure may be formed under each tip of the second bank BNK2. A thickness of the first bank BNK1 may be greater than the sum of thicknesses of the second through fourth banks BNK2 through BNK4. The thickness of each of the third and fourth banks BNK3 and BNK4 may be greater than the thickness of the second bank BNK2.

The first and second banks BNK1 and BNK2 may include different metal materials. An etching rate of the first bank BNK1 and an etching rate of the second bank BNK2 may be different from each other. For example, the etching rate of the first bank BNK1 may be higher than that of the second bank BNK2 in a wet etching process, and the first bank BNK1 may be etched more than the second bank BNK2 in the process of forming the first through third emission areas EA1 through EA3. Therefore, the profile of the first and second banks BNK1 and BNK2 may be determined by a difference in etching rate between the first and second banks BNK1 and BNK2. The first bank BNK1 may include a metal material having high electrical conductivity, and the second bank BNK2 may include a material having low reflectivity. For example, the first bank BNK1 may include aluminum (Al), and the second bank BNK2 may include titanium (Ti). However, the present disclosure is not limited thereto.

The third bank BNK3 may include an inorganic insulating material. The third bank BNK3 may include, but is not limited to, at least one of a silicon nitride layer, a silicon oxynitride layer, a silicon oxide layer, a titanium oxide layer, an aluminum oxide layer, and an amorphous silicon layer.

The fourth bank BNK4 may include an inorganic insulating material different from that of the third bank BNK3. The fourth bank BNK4 may include a different material from the third bank BNK3 among a silicon nitride layer, a silicon oxynitride layer, a silicon oxide layer, a titanium oxide layer, an aluminum oxide layer, and an amorphous silicon layer.

Since the display device 10 includes the third and fourth banks BNK3 and BNK4 including different inorganic insulating materials, the encapsulation area of each of the first through third inorganic layers TL1 through TL3 can be secured. For example, the horizontal area of the bank BNK may be limited to secure the planar area of each of the first through third emission areas EA1 through EA3. Therefore, the third and fourth banks BNK3 and BNK4 may increase the thickness of the bank BNK, and each of the first through third inorganic layers TL1 through TL3 may secure the encapsulation area of the bank BNK, thereby blocking a moisture penetration path. As a result, the reliability of the first through third light emitting elements ED1 through ED3 can be improved. In addition, at least one of the third and fourth banks BNK3 and BNK4 may maximize the encapsulation effect by including the same inorganic insulating material as the first through third inorganic layers TL1 through TL3.

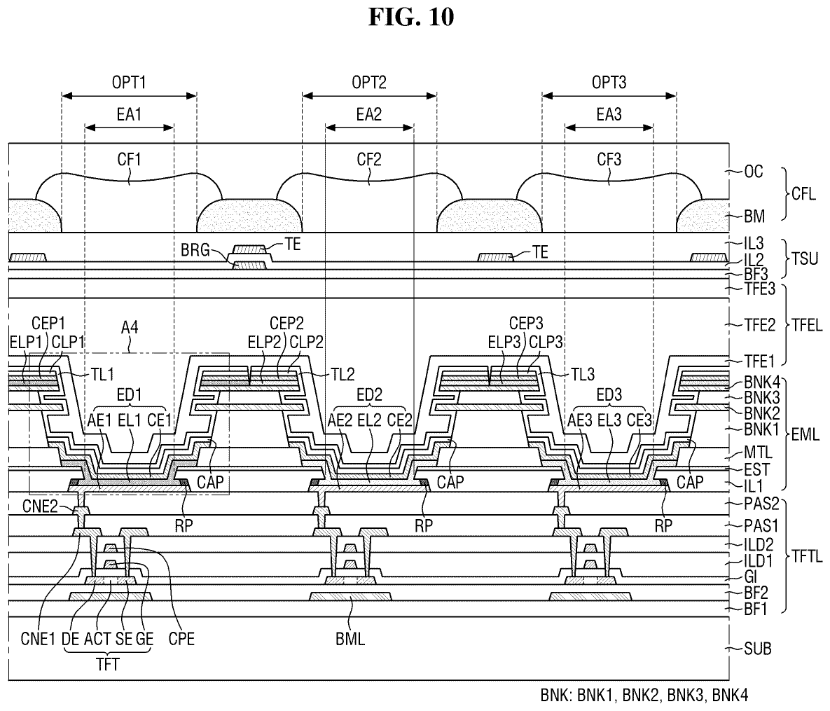

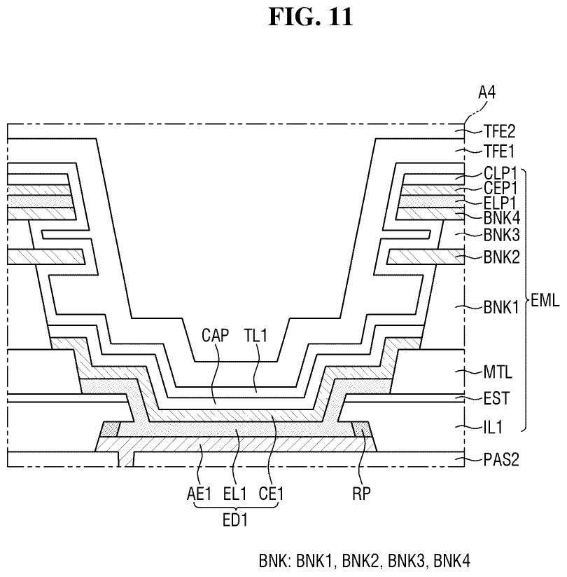

FIG. 10 is a cross-sectional view illustrating pixels of a display device 10 according to an embodiment. FIG. 11 is an enlarged view of area A4 of FIG. 10. The display device 10 of FIGS. 10 and 11 is different from the display device 10 of FIGS. 4 and 5 in the configuration of a bank BNK. The same elements as those described above will be briefly described or will not be described.

Referring to FIGS. 10 and 11, a display panel 100 may include a display unit DU, a touch sensing unit TSU, and a color filter layer CFL. The display unit DU may include a substrate SUB, a thin-film transistor layer TFTL, a light emitting element layer EML, and an encapsulation layer TFEL.

The light emitting element layer EML may be disposed on the thin-film transistor layer TFTL. The light emitting element layer EML may include first through third light emitting elements ED1 through ED3, residual patterns RP, a first insulating layer IL1, an etch control layer EST, capping layers CAP, a conductive layer MTL, the bank BNK, first through third organic patterns ELP1 through ELP3, first through third electrode patterns CEP1 through CEP3, first through third capping patterns CLP1 through CLP3, and first through third inorganic layers TL1 through TL3.

The bank BNK may be disposed on the conductive layer MTL to define first through third emission areas EA1 through EA3. The bank BNK may surround the first through third emission areas EA1 through EA3 in a plan view. The bank BNK may include first through fourth banks BNK1 through BNK4.

The first bank BNK1 may be disposed on the conductive layer MTL, the second bank BNK2 may be disposed on the first bank BNK1, the third bank BNK3 may be disposed on the second bank BNK2, and the fourth bank BNK4 may be disposed on the third bank BNK3. Side surfaces of the first bank BNK1 may be recessed inward from side surfaces of the second bank BNK2, and side surfaces of the third bank BNK3 may be recessed inward from side surfaces of the fourth bank BNK4. Since the side surfaces of the second bank BNK2 protrude from the side surfaces of the first and third banks BNK1 and BNK3 toward the first emission area EA1, the second bank BNK2 may include protruding tips. Since the side surfaces of the fourth bank BNK4 protrude from the side surfaces of the third bank BNK3 toward the first emission area EA1, the fourth bank BNK4 may include protruding tips. Accordingly, an undercut structure may be formed under each tip of each of the second and fourth banks BNK2 and BNK4. A thickness of the first bank BNK1 may be greater than the sum of thicknesses of the second through fourth banks BNK2 through BNK4. The thickness of the third bank BNK3 may be greater than the thickness of each of the second and fourth banks BNK2 and BNK4.

The first and second banks BNK1 and BNK2 may include different metal materials. The third and fourth banks BNK3 and BNK4 may include different metal materials. An etching rate of the first bank BNK1 and an etching rate of the second bank BNK2 may be different from each other. An etching rate of the third bank BNK3 and an etching rate of the fourth bank BNK4 may be different from each other. For example, the etching rate of each of the first and third banks BNK1 and BNK3 may be higher than that of each of the second and fourth banks BNK2 and BNK4 in a wet etching process, and the first and third banks BNK1 and BNK3 may be etched more than the second and fourth banks BNK2 and BNK4 in the process of forming the first through third emission areas EA1 through EA3. Therefore, the profile of the first through fourth banks BNK1 through BNK4 may be determined by a difference in etching rate between the first through fourth banks BNK1 through BNK4. The first and third banks BNK1 and BNK3 may include a metal material having high electrical conductivity, and the second and fourth banks BNK2 and BNK4 may include a material having low reflectivity. For example, the first and third banks BNK1 and BNK3 may include aluminum (Al), and the second and fourth banks BNK2 and BNK4 may include titanium (Ti). However, the present disclosure is not limited thereto.

The first inorganic layer TL1 may be disposed on the capping layer CAP of the first emission area EA1 and the first capping pattern CLP1. The first inorganic layer TL1 may cover an upper surface of the capping layer CAP in the first emission area EA1. The first inorganic layer TL1 may cover the side surfaces of the first bank BNK1, lower and side surfaces of the tips of the second bank BNK2, the side surfaces of the third bank BNK3, lower and side surfaces of the tips of the fourth bank BNK4, side surfaces of the first organic pattern ELP1, side surfaces of the first electrode pattern CEP1, and upper and side surfaces of the first capping pattern CLP1.

The second inorganic layer TL2 may be disposed on the capping layer CAP of the second emission area EA2 and the second capping pattern CLP2. The second inorganic layer TL2 may cover an upper surface of the capping layer CAP in the second emission area EA2. The second inorganic layer TL2 may cover the side surfaces of the first bank BNK1, the lower and side surfaces of the tips of the second bank BNK2, the side surfaces of the third bank BNK3, the lower and side surfaces of the tips of the fourth bank BNK4, side surfaces of the second organic pattern ELP2, side surfaces of the second electrode pattern CEP2, and upper and side surfaces of the second capping pattern CLP2.

The third inorganic layer TL3 may be disposed on the capping layer CAP of the third emission area EA3 and the third capping pattern CLP3. The third inorganic layer TL3 may cover an upper surface of the capping layer CAP in the third emission area EA3. The third inorganic layer TL3 may cover the side surfaces of the first bank BNK1, the lower and side surfaces of the tips of the second bank BNK2, the side surfaces of the third bank BNK3, the lower and side surfaces of the tips of the fourth bank BNK4, side surfaces of the third organic pattern ELP3, side surfaces of the third electrode pattern CEP3, and upper and side surfaces of the third capping pattern CLP3.

Since the display device 10 includes the third and fourth banks BNK3 and BNK4 including different metal materials, the encapsulation area of each of the first through third inorganic layers TL1 through TL3 can be secured. For example, the horizontal area of the bank BNK may be limited to secure the planar area of each of the first through third emission areas EA1 through EA3. Therefore, the third and fourth banks BNK3 and BNK4 may increase the thickness of the bank BNK, and each of the first through third inorganic layers TL1 through TL3 may secure the encapsulation area of the bank BNK, thereby blocking a moisture penetration path. As a result, the reliability of the first through third light emitting elements ED1 through ED3 can be improved.

The first through third light emitting elements ED1 through ED3 may be formed through deposition and etching processes rather than a mask process. Since the first and third banks BNK1 and BNK3 include a different metal material from the second and fourth banks BNK2 and BNK4, each inner wall of the bank BNK may have a two-tip structure. In the display device 10, different layers may be individually formed in the first through third emission areas EA1 through EA3 through a deposition process. For example, an island shaped first light emitting layer EL1 may be deposited in the first emission area EA1 due to tips formed to surround the first emission area EA1 in the process of depositing an organic material without using a mask, and the organic material which is disposed in areas other than the first emission area EA1 may be removed through an etching process.

In the display device 10 including the first through fourth banks BNK1 through BNK4, the first through third light emitting elements ED1 through ED3 can be easily formed through deposition and etching processes using the two-tip structure, and penetration of moisture into the first through third light emitting elements ED1 through ED3 can be prevented.

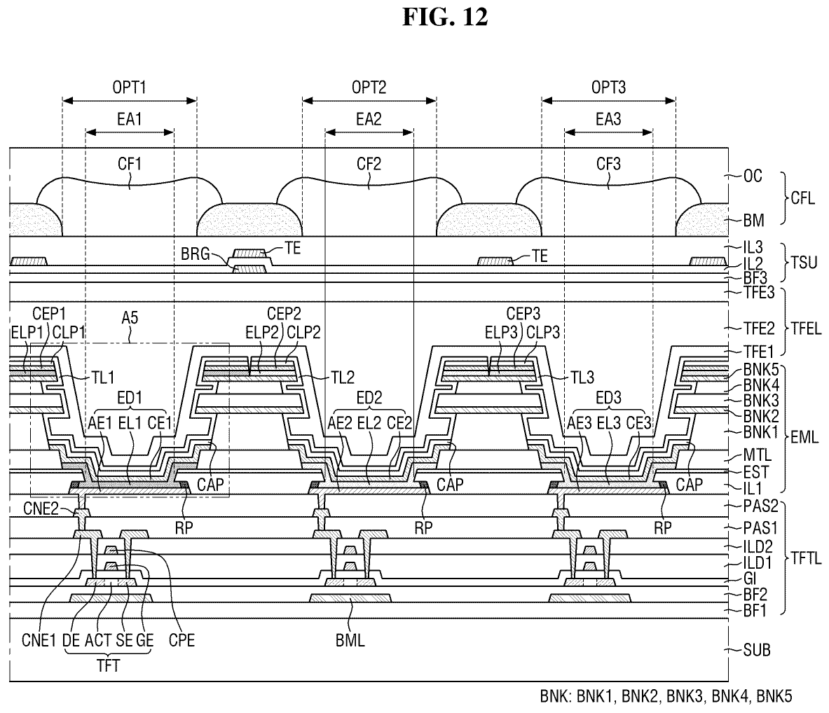

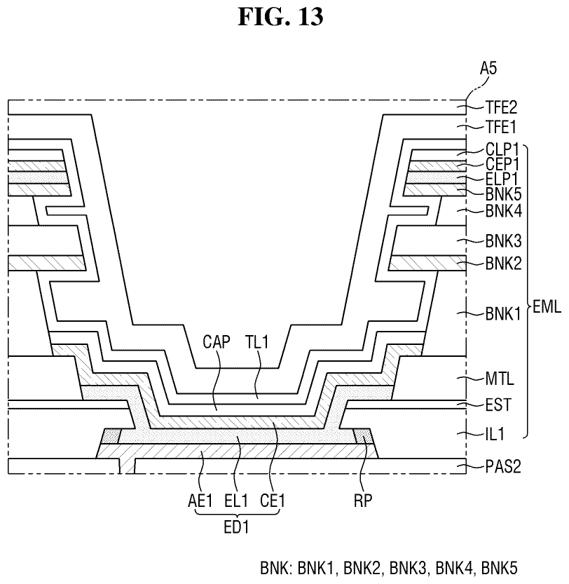

FIG. 12 is a cross-sectional view illustrating pixels of a display device 10 according to an embodiment. FIG. 13 is an enlarged view of area A5 of FIG. 12. The display device 10 of FIGS. 12 and 13 is different from the display device 10 of FIGS. 4 and 5 in the configuration of a bank BNK. The same elements as those described above will be briefly described or will not be described.

Referring to FIGS. 12 and 13, a display panel 100 may include a display unit DU, a touch sensing unit TSU, and a color filter layer CFL. The display unit DU may include a substrate SUB, a thin-film transistor layer TFTL, a light emitting element layer EML, and an encapsulation layer TFEL.

The light emitting element layer EML may be disposed on the thin-film transistor layer TFTL. The light emitting element layer EML may include first through third light emitting elements ED1 through ED3, residual patterns RP, a first insulating layer IL1, an etch control layer EST, capping layers CAP, a conductive layer MTL, the bank BNK, first through third organic patterns ELP1 through ELP3, first through third electrode patterns CEP1 through CEP3, first through third capping patterns CLP1 through CLP3, and first through third inorganic layers TL1 through TL3.

The bank BNK may be disposed on the conductive layer MTL to define first through third emission areas EA1 through EA3. The bank BNK may surround the first through third emission areas EA1 through EA3 in a plan view. The bank BNK may include first through fifth banks BNK1 through BNK5.

The first bank BNK1 may be disposed on the conductive layer MTL, the second bank BNK2 may be disposed on the first bank BNK1, the third bank BNK3 may be disposed on the second bank BNK2, the fourth bank BNK4 may be disposed on the third bank BNK3, and the fifth bank BNK5 may be disposed on the fourth bank BNK4. Side surfaces of the first bank BNK1 may be recessed inward from side surfaces of the second and third banks BNK2 and BNK3, and side surfaces of the fourth bank BNK4 may be recessed inward from side surfaces of the fifth bank BNK5. Since the side surfaces of the second bank BNK2 protrude from the side surfaces of the first and fourth banks BNK1 and BNK4 toward the first emission area EA1, the second bank BNK2 may include protruding tips. Since the side surfaces of the fifth bank BNK5 protrude from the side surfaces of the fourth bank BNK4 toward the first emission area EA1, the fifth bank BNK5 may include protruding tips. Accordingly, an undercut structure may be formed under each tip of each of the second and fifth banks BNK2 and BNK5. A thickness of the first bank BNK1 may be greater than a thickness of each of the second through fifth banks BNK2 through BNK5. The thickness of each of the third and fourth banks BNK3 and BNK4 may be greater than the thickness of each of the second and fifth banks BNK2 and BNK5.

The first and second banks BNK1 and BNK2 may include different metal materials. The third bank BNK3 may include an inorganic insulating material. The third bank BNK3 may include, but is not limited to, at least one of a silicon nitride layer, a silicon oxynitride layer, a silicon oxide layer, a titanium oxide layer, an aluminum oxide layer, and an amorphous silicon layer. The fourth and fifth banks BNK4 and BNK5 may include different metal materials. An etching rate of the first bank BNK1 may be different from etching rates of the second and third banks BNK2 and BNK3. An etching rate of the fourth bank BNK4 and an etching rate of the fifth bank BNK5 may be different from each other. For example, the etching rate of each of the first and fourth banks BNK1 and BNK4 may be higher than that of each of the second, third and fifth banks BNK2, BNK3 and BNK5 in a wet etching process, and the first and fourth banks BNK1 and BNK4 may be etched more than the second, third and fifth banks BNK2, BNK3 and BNK5 in the process of forming the first through third emission areas EA1 through EA3. Therefore, the profile of the first through fifth banks BNK1 through BNK5 may be determined by a difference in etching rate between the first through fifth banks BNK1 through BNK5. The first and fourth banks BNK1 and BNK4 may include a metal material having high electrical conductivity, and the second and fifth banks BNK2 and BNK5 may include a material having low reflectivity. For example, the first and fourth banks BNK1 and BNK4 may include aluminum (Al), and the second and fifth banks BNK2 and BNK5 may include titanium (Ti). However, the present disclosure is not limited thereto.

The first inorganic layer TL1 may be disposed on the capping layer CAP of the first emission area EA1 and the first capping pattern CLP1. The first inorganic layer TL1 may cover an upper surface of the capping layer CAP in the first emission area EA1. The first inorganic layer TL1 may cover the side surfaces of the first bank BNK1, lower and side surfaces of the tips of the second bank BNK2, the side surfaces of the third and fourth banks BNK3 and BNK4, lower and side surfaces of the tips of the fifth bank BNK5, side surfaces of the first organic pattern ELP1, side surfaces of the first electrode pattern CEP1, and upper and side surfaces of the first capping pattern CLP1.

The second inorganic layer TL2 may be disposed on the capping layer CAP of the second emission area EA2 and the second capping pattern CLP2. The second inorganic layer TL2 may cover an upper surface of the capping layer CAP in the second emission area EA2. The second inorganic layer TL2 may cover the side surfaces of the first bank BNK1, the lower and side surfaces of the tips of the second bank BNK2, the side surfaces of the third and fourth banks BNK3 and BNK4, the lower and side surfaces of the tips of the fifth bank BNK5, side surfaces of the second organic pattern ELP2, side surfaces of the second electrode pattern CEP2, and upper and side surfaces of the second capping pattern CLP2.

The third inorganic layer TL3 may be disposed on the capping layer CAP of the third emission area EA3 and the third capping pattern CLP3. The third inorganic layer TL3 may cover an upper surface of the capping layer CAP in the third emission area EA3. The third inorganic layer TL3 may cover the side surfaces of the first bank BNK1, the lower and side surfaces of the tips of the second bank BNK2, the side surfaces of the third and fourth banks BNK3 and BNK4, the lower and side surfaces of the tips of the fifth bank BNK5, side surfaces of the third organic pattern ELP3, side surfaces of the third electrode pattern CEP3, and upper and side surfaces of the third capping pattern CLP3.

Since the display device 10 includes the third bank BNK3 including an inorganic insulating material and the fourth and fifth banks BNK4 and BNK5 including different metal materials, the encapsulation area of each of the first through third inorganic layers TL1 through TL3 can be secured. For example, the horizontal area of the bank BNK may be limited to secure the planar area of each of the first through third emission areas EA1 through EA3. Therefore, the third through fifth banks BNK3 through BNK5 may increase the thickness of the bank BNK, and each of the first through third inorganic layers TL1 through TL3 may secure the encapsulation area of the bank BNK, thereby blocking a moisture penetration path. As a result, the reliability of the first through third light emitting elements ED1 through ED3 can be improved.

The first through third light emitting elements ED1 through ED3 may be formed through deposition and etching processes rather than a mask process. Since the first and fourth banks BNK1 and BNK4 include a different metal material from the second and fifth banks BNK2 and BNK5, each inner wall of the bank BNK may have a two-tip structure. In the display device 10, different layers may be individually formed in the first through third emission areas EA1 through EA3 through a deposition process. For example, an island shaped first light emitting layer EL1 may be deposited in the first emission area EA1 due to tips formed to surround the first emission area EA1 in the process of depositing an organic material without using a mask, and the organic material disposed in areas other than the first emission area EA1 may be removed through an etching process.

In the display device 10 including the first through fifth banks BNK1 through BNK5, the first through third light emitting elements ED1 through ED3 can be easily formed through deposition and etching processes using the two-tip structure, and penetration of moisture into the first through third light emitting elements ED1 through ED3 can be prevented.

FIGS. 14 through 21 are cross-sectional views illustrating a process of manufacturing a display device 10 according to an embodiment.

In FIG. 14, first through third pixel electrodes AE1 through AE3 may be formed to be spaced apart from each other on a thin-film transistor layer TFTL. The first through third pixel electrodes AE1 through AE3 may include at least one of silver (Ag), copper (Cu), aluminum (Al), nickel (Ni), and lanthanum (La). For another example, the first through third pixel electrodes AE1 through AE3 may include a material such as indium tin oxide (ITO), indium zinc oxide (IZO), or indium tin zinc oxide (ITZO). For another example, the first through third pixel electrodes AE1 through AE3 may have a stacked structure of ITO/Ag/ITO, ITO/Ag/IZO, or ITO/Ag/ITZO/IZO.

A sacrificial layer SFL may be disposed on the first through third pixel electrodes AE1 through AE3. The sacrificial layer SFL may be disposed between upper surfaces of the first through third pixel electrodes AE1 through AE3 and a first insulating layer IL1. The sacrificial layer SFL may include an oxide semiconductor. For example, the sacrificial layer SFL may include at least one of indium gallium zinc oxide (IGZO), zinc tin oxide (ZTO), and indium zinc oxide (IZO).

The first insulating layer IL1 may be disposed on the thin-film transistor layer TFTL and the sacrificial layer SFL. The first insulating layer IL1 may include an inorganic insulating material. The first insulating layer IL1 may include, but is not limited to, at least one of a silicon nitride layer, a silicon oxynitride layer, a silicon oxide layer, a titanium oxide layer, an aluminum oxide layer, and an amorphous silicon layer.

An etch control layer EST may be disposed on the first insulating layer IL1. The etch control layer EST may function as an etching stopper. Optionally, the etch control layer EST may be omitted.

A conductive layer MTL may be disposed on the etch control layer EST. The conductive layer MTL may include a metal material with high electrical conductivity. For example, the conductive layer MTL may include, but is not limited to, aluminum (Al). The etch control layer EST may have good etching selectivity with the conductive layer MTL disposed on the etch control layer EST to an etchant etching the conductive layer MTL.

A first bank BNK1 may be disposed on the conductive layer MTL, a second bank BNK2 may be disposed on the first bank BNK1, a third bank BNK3 may be disposed on the second bank BNK2, and a fourth bank BNK4 may be disposed on the third bank BNK3. A thickness of the first bank BNK1 may be greater than the sum of thicknesses of the second through fourth banks BNK2 through BNK4, and the thickness of the third bank BNK3 may be greater than the thickness of each of the second and fourth banks BNK2 and BNK4. The first bank BNK1 may include a metal material having high electrical conductivity, and the second bank BNK2 may include a material having low reflectivity. For example, the first bank BNK1 may include aluminum (Al), and the second bank BNK2 may include titanium (Ti). However, the present disclosure is not limited thereto.

The third bank BNK3 may include an inorganic insulating material. The third bank BNK3 may include, but is not limited to, at least one of a silicon nitride layer, a silicon oxynitride layer, a silicon oxide layer, a titanium oxide layer, an aluminum oxide layer, and an amorphous silicon layer. The fourth bank BNK4 may include a metal material. The fourth bank BNK4 may include one of molybdenum (Mo), aluminum (Al), chromium (Cr), gold (Au), titanium (Ti), nickel (Ni), neodymium (Nd), and copper (Cu).

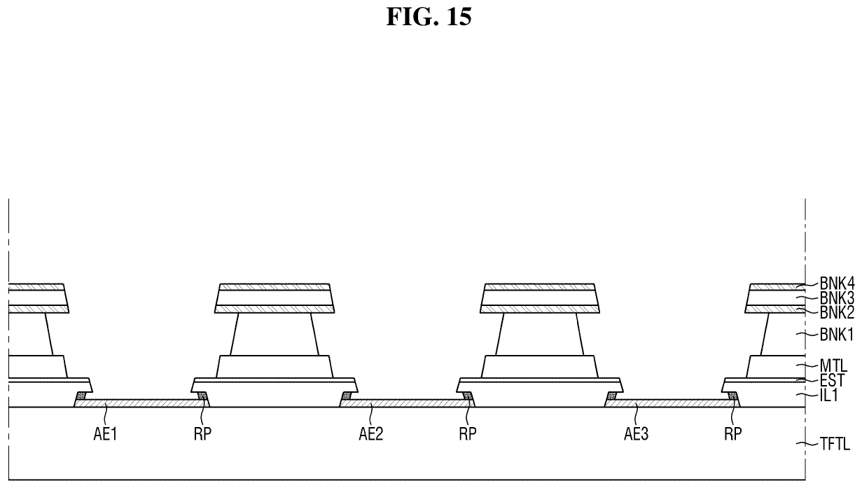

In FIG. 15, the fourth bank BNK4, the third bank BNK3, the second bank BNK2, the first bank BNK1, and the conductive layer MTL may be sequentially etched to form a plurality of holes. The holes may be disposed in areas corresponding to first through third emission areas EA1 through EA3. The conductive layer MTL and the first through fourth banks BNK1 through BNK4 may be etched by performing at least one of a dry etching process and a wet etching process. The etch control layer EST may protect the first through third pixel electrodes AE1 through AE3 in the process of etching the bank BNK and the conductive layer MTL. The first and second banks BNK1 and BNK2 may include different metal materials, and etching rates of the first and second banks BNK1 and BNK2 may be different from each other. The etching rate of the first bank BNK1 may be higher than that of the second bank BNK2, and the first bank BNK1 may be etched more than the second bank BNK2. Therefore, the profile of the first and second banks BNK1 and BNK2 may be determined by a difference in etching rate between the first and second banks BNK1 and BNK2. The second bank BNK2 may include tips protruding from the first bank BNK1 toward the holes. Side surfaces of the first bank BNK1 may be recessed inward from side surfaces of the second bank BNK2. An undercut structure may be formed under each tip of the second bank BNK2.

The etch control layer EST, the first insulating layer IL1, and the sacrificial layer SFL may be etched by performing at least one of a dry etching process and a wet etching process. As the etch control layer EST, the first insulating layer IL1 and the sacrificial layer SFL are etched, at least a portion of the upper surface of each of the first through third pixel electrodes AE1 through AE3 may be exposed. The sacrificial layer SFL may be etched more than the first insulating layer IL1 in a plan view. When the sacrificial layer SFL is etched, residual patterns RP may remain between the first insulating layer IL1 and the first pixel electrode AE1. Accordingly, side surfaces of the residual patterns RP may be recessed inward from side surfaces of the first insulating layer IL1.

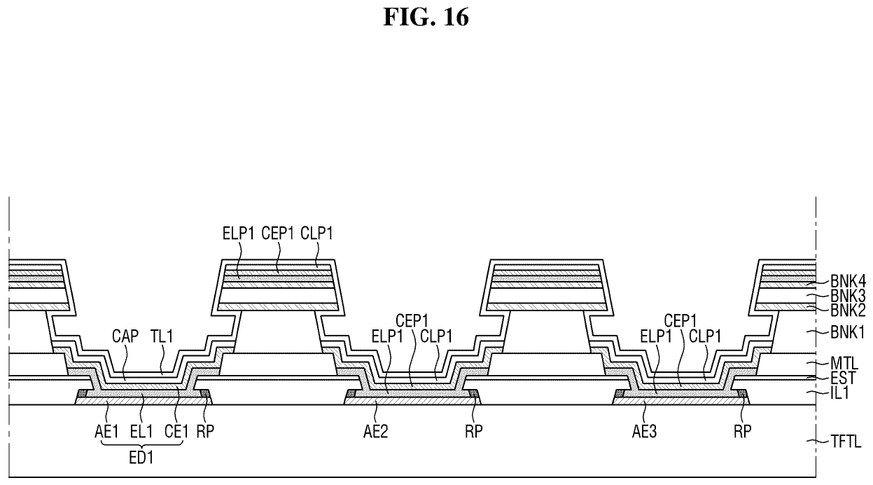

In FIG. 16, a first light emitting layer ELI may be directly disposed on the first pixel electrode AE1 in the first emission area EA1. A portion of the first light emitting layer EL1 may fill a space surrounded by the first pixel electrode AE1, the residual patterns RP and the first insulating layer IL1, and another portion of the first light emitting layer EL1 may cover upper surfaces of edges of the etch control layer EST and the side surfaces of the first insulating layer IL1.

An organic material for forming the first light emitting layer EL1 and a first organic pattern ELP1 may be deposited on the entire surface of the display device 10. The first light emitting layer ELI and the first organic pattern ELP1 may be deposited in the same process and may be disconnected due to the tips of the second bank BNK2. A portion of the first organic pattern ELP1 may be disposed on the fourth bank BNK4, another portion of the first organic pattern ELP1 may be directly disposed on the second pixel electrode AE2 in the second emission area EA2, and another portion of the first organic pattern ELP1 may be directly disposed on the third pixel electrode AE3 in the third emission area EA3.

A first common electrode CE1 may be directly disposed on the first light emitting layer EL1 in the first emission area EA1. The first common electrode CE1 may contact side surfaces of the conductive layer MTL and upper surfaces of edges of the conductive layer MTL. The first common electrode CE1 may include a transparent conductive material and transmit light generated from the first light emitting layer ELI. Therefore, a first light emitting element ED1 may be disposed in a hole formed by the bank BNK and may emit light through the first emission area EA1.

A metal material for forming the first common electrode CE1 and a first electrode pattern CEP1 may be deposited on the entire surface of the display device 10. The first common electrode CE1 and the first electrode pattern CEP1 may be deposited in the same process and may be disconnected due to the tips of the second bank BNK2. A portion of the first electrode pattern CEP1 may be disposed on the first organic pattern ELP1 on the fourth bank BNK4, and another portion of the first electrode pattern CEP1 may be directly disposed on the first organic pattern ELP1 in each of the second and third emission areas EA2 and EA3. Therefore, the first electrode pattern CEP1 may be disposed on the first organic pattern ELP1 in areas other than the first emission area EA1.

A capping layer CAP may be disposed on the first common electrode CE1 in the first emission area EA1. The capping layer CAP may include an inorganic insulating material and may cover the first light emitting element ED1. The capping layer CAP may prevent the first light emitting element ED1 from being damaged by external air. For example, the capping layer CAP may include, but is not limited to, at least one of a silicon nitride layer, a silicon oxynitride layer, a silicon oxide layer, a titanium oxide layer, an aluminum oxide layer, and an amorphous silicon layer.

An inorganic material for forming the capping layer CAP and a first capping pattern CLP1 may be deposited on the entire surface of the display device 10. The capping layer CAP and the first capping pattern CLP1 may be deposited in the same process and may be disconnected due to the tips of the second bank BNK2. A portion of the first capping pattern CLP1 may be disposed on the first electrode pattern CEP1 on the fourth bank BNK4, and the other portion of the first capping pattern CLP1 may be disposed on the first electrode pattern CEP1 in each of the second and third emission areas EA2 and EA3. Therefore, the first capping pattern CLP1 may be disposed on the first electrode pattern CEP1 in the areas other than the first emission area EA1.

An inorganic material for forming a first inorganic layer TL1 may be deposited on the entire surface of the display device 10. The first inorganic layer TL1 may cover an upper surface of the capping layer CAP in the first emission area EA1 and may cover an upper surface of the first capping pattern CLP1 in the second and third emission areas EA2 and EA3. The first inorganic layer TL1 may cover the side surfaces of the first bank BNK1, lower and side surfaces of the tips of the second bank BNK2, side surfaces of the third and fourth banks BNK3 and BNK4, side surfaces of the first organic pattern ELP1, side surfaces of the first electrode pattern CEP1, and upper and side surfaces of the first capping pattern CLP1. The first inorganic layer TL1 may include an inorganic material to prevent oxygen or moisture from penetrating into the first light emitting element ED1. The first inorganic layer TL1 may be an inorganic encapsulation layer. For example, the first inorganic layer TL1 may include, but is not limited to, at least one of a silicon nitride layer, a silicon oxynitride layer, a silicon oxide layer, a titanium oxide layer, an aluminum oxide layer, and an amorphous silicon layer.

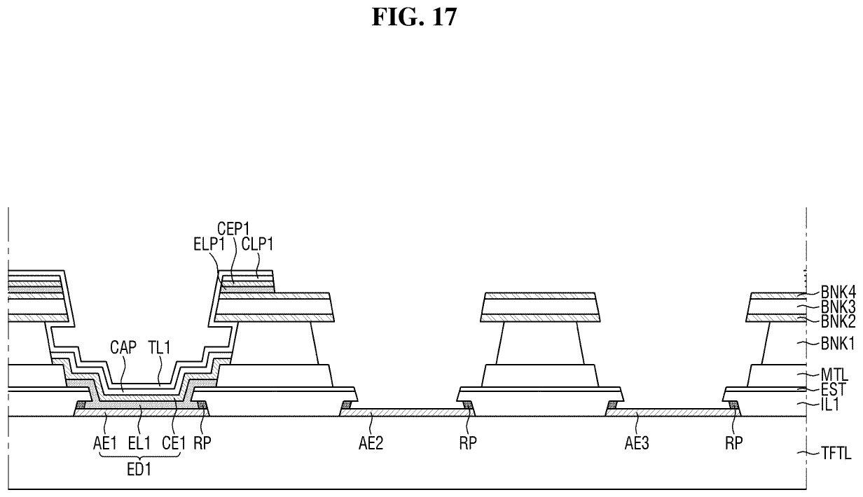

In FIG. 17, the first inorganic layer TL1, the first capping pattern CLP1, the first electrode pattern CEP1, and the first organic pattern ELP1 not disposed in the first emission area EA1 and an area adjacent to the first emission area EA1 may be etched through an etching process. For example, the first inorganic layer TL1, the first capping pattern CLP1, the first electrode pattern CEP1, and the first organic pattern ELP1 may be etched by performing at least one of a dry etching process and a wet etching process. Accordingly, the second pixel electrode AE2 may be exposed in the second emission area EA2, and the third pixel electrode AE3 may be exposed in the third emission area EA3.

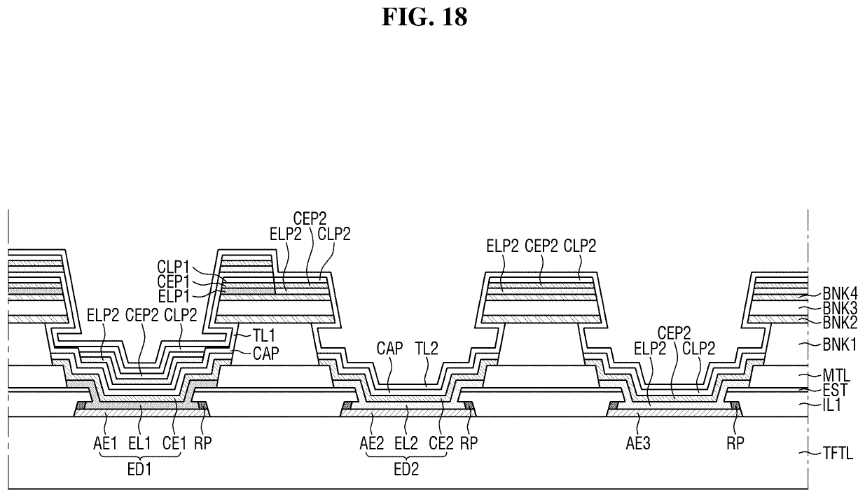

In FIG. 18, a second light emitting layer EL2 may be directly disposed on the second pixel electrode AE2 in the second emission area EA2. A portion of the second light emitting layer EL2 may fill a space surrounded by the second pixel electrode AE2, the residual patterns RP and the first insulating layer IL1, and another portion of the second light emitting layer EL2 may cover the upper surfaces of the edges of the etch control layer EST and the side surfaces of the first insulating layer IL1.

An organic material for forming the second light emitting layer EL2 and a second organic pattern ELP2 may be deposited on the entire surface of the display device 10. The second light emitting layer EL2 and the second organic pattern ELP2 may be deposited in the same process and may be disconnected due to the tips of the second bank BNK2. A portion of the second organic pattern ELP2 may be disposed on the fourth bank BNK4 disposed adjacent to the second emission area EA2, another portion of the second organic pattern ELP2 may be directly disposed on the third pixel electrode AE3 in the third emission area EA3, and another portion of the second organic pattern ELP2 may be disposed on the first inorganic layer TL1 in the first emission area EA1.

A second common electrode CE2 may be directly disposed on the second light emitting layer EL2 in the second emission area EA2. The second common electrode CE2 may contact the side surfaces of the conductive layer MTL and the upper surfaces of the edges of the conductive layer MTL. The second common electrode CE2 may include a transparent conductive material and transmit light generated from the second light emitting layer EL2. Therefore, a second light emitting element ED2 may be disposed in a hole formed by the bank BNK and may emit light through the second emission area EA2.

A metal material for forming the second common electrode CE2 and a second electrode pattern CEP2 may be deposited on the entire surface of the display device 10. The second common electrode CE2 and the second electrode pattern CEP2 may be deposited in the same process and may be disconnected due to the tips of the second bank BNK2. A portion of the second electrode pattern CEP2 may be disposed on the second organic pattern ELP2 on the fourth bank BNK4, and another portion of the second electrode pattern CEP2 may be directly disposed on the second organic pattern ELP2 in each of the first and third emission areas EA1 and EA3. Therefore, the second electrode pattern CEP2 may be disposed on the second organic pattern ELP2 in areas other than the second emission area EA2.

A capping layer CAP may be disposed on the second common electrode CE2 in the second emission area EA2. The capping layer CAP may include an inorganic insulating material and may cover the second light emitting element ED2. The capping layer CAP may prevent the second light emitting element ED2 from being damaged by external air.

An inorganic material for forming the capping layer CAP and a second capping pattern CLP2 may be deposited on the entire surface of the display device 10. The capping layer CAP and the second capping pattern CLP2 may be deposited in the same process and may be disconnected due to the tips of the second bank BNK2. A portion of the second capping pattern CLP2 may be disposed on the second electrode pattern CEP2 on the fourth bank BNK4, and another portion of the second capping pattern CLP2 may be disposed on the second electrode pattern CEP2 in each of the first and third emission area EA1 and EA3. Therefore, the second capping pattern CLP2 may be disposed on the second electrode pattern CEP2 in the areas other than the second emission area EA2.

An inorganic material for forming a second inorganic layer TL2 may be deposited on the entire surface of the display device 10. The second inorganic layer TL2 may cover an upper surface of the capping layer CAP in the second emission area EA2 and may cover an upper surface of the second capping pattern CLP2 in the first and third emission areas EA1 and EA3. The second inorganic layer TL2 may cover the side surfaces of the first bank BNK1, the lower and side surfaces of the tips of the second bank BNK2, the side surfaces of the third and fourth banks BNK3 and BNK4, side surfaces of the second organic pattern ELP2, side surfaces of the second electrode pattern CEP2, and upper and side surfaces of the second capping pattern CLP2. The second inorganic layer TL2 may include an inorganic material to prevent oxygen or moisture from penetrating into the second light emitting element ED2. The second inorganic layer TL2 may be an inorganic encapsulation layer. For example, the second inorganic layer TL2 may be made of at least one of the materials exemplified in the description of the first inorganic layer TL1.

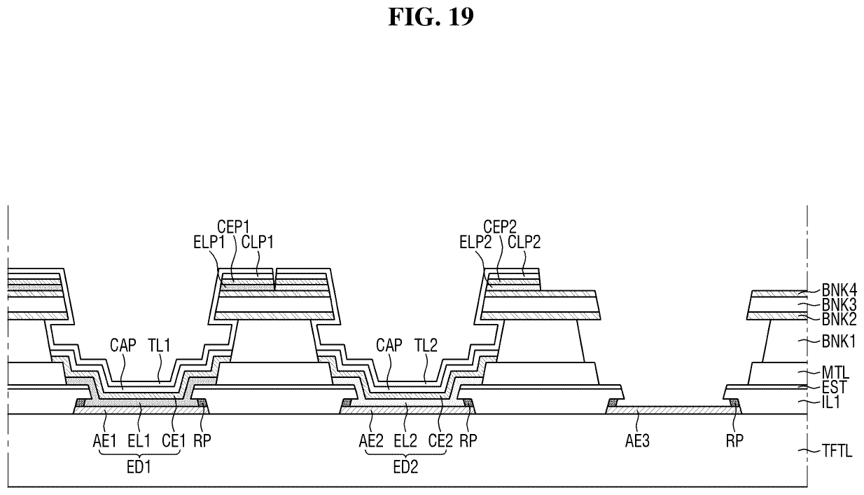

In FIG. 19, the second inorganic layer TL2, the second capping pattern CLP2, the second electrode pattern CEP2, and the second organic pattern ELP2 not disposed in the second emission area EA2 and an area adjacent to the second emission area EA2 may be etched through an etching process. For example, the second inorganic layer TL2, the second capping pattern CLP2, the second electrode pattern CEP2, and the second organic pattern ELP2 may be etched by performing at least one of a dry etching process and a wet etching process. Accordingly, the third pixel electrode AE3 may be exposed in the third emission area EA3.

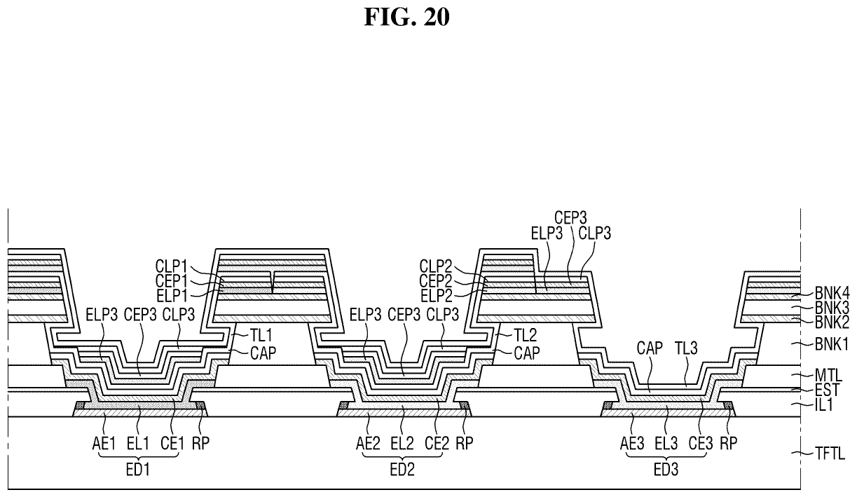

In FIG. 20, a third light emitting layer EL3 may be directly disposed on the third pixel electrode AE3 in the third emission area EA3. A portion of the third light emitting layer EL3 may fill a space surrounded by the third pixel electrode AE3, the residual patterns RP and the first insulating layer IL1, and another portion of the third light emitting layer EL3 may cover the upper surfaces of the edges of the etch control layer EST and the side surfaces of the first insulating layer IL1.

An organic material for forming the third light emitting layer EL3 and a third organic pattern ELP3 may be deposited on the entire surface of the display device 10. The third light emitting layer EL3 and the third organic pattern ELP3 may be deposited in the same process and may be disconnected due to the tips of the second bank BNK2. A portion of the third organic pattern ELP3 may be disposed on the fourth bank BNK4 adjacent to the third emission area EA3, and another portion of the third organic pattern ELP3 may be disposed on the first inorganic layer TL1 or the second inorganic layer TL2.

A third common electrode CE3 may be directly disposed on the third light emitting layer EL3 in the third emission area EA3. The third common electrode CE3 may contact the side surfaces of the conductive layer MTL and the upper surfaces of the edges of the conductive layer MTL. The third common electrode CE3 may include a transparent conductive material and transmit light generated from the third light emitting layer EL3. Therefore, a third light emitting element ED3 may be disposed in a hole formed by the bank BNK and may emit light through the third emission area EA3.

A metal material for forming the third common electrode CE3 and a third electrode pattern CEP3 may be deposited on the entire surface of the display device 10. The third common electrode CE3 and the third electrode pattern CEP3 may be deposited in the same process and may be disconnected due to the tips of the second bank BNK2. A portion of the third electrode pattern CEP3 may be disposed on the third organic pattern ELP3 on the fourth bank BNK4, and another portion of the third electrode pattern CEP3 may be directly disposed on the third organic pattern ELP3 in each of the first and second emission areas EA1 and EA2. Therefore, the third electrode pattern CEP3 may be disposed on the third organic pattern ELP3 in areas other than the third emission area EA3.

A capping layer CAP may be disposed on the third common electrode CE3 in the third emission area EA3. The capping layer CAP may include an inorganic insulating material and may cover the third light emitting element ED3. The capping layer CAP may prevent the third light emitting element ED3 from being damaged by external air.

An inorganic material for forming the capping layer CAP and a third capping pattern CLP3 may be deposited on the entire surface of the display device 10. The capping layer CAP and the third capping pattern CLP3 may be deposited in the same process and may be disconnected due to the tips of the second bank BNK2. A portion of the third capping pattern CLP3 may be disposed on the third electrode pattern CEP3 on the fourth bank BNK4, and another portion of the third capping pattern CLP3 may be disposed on the third electrode pattern CEP3 in each of the first and second emission areas EA1 and EA2. Therefore, the third capping pattern CLP3 may be disposed on the third electrode pattern CEP3 in the areas other than the third emission area EA3.

An inorganic material for forming a third inorganic layer TL3 may be deposited on the entire surface of the display device 10. The third inorganic layer TL3 may cover an upper surface of the capping layer CAP in the third emission area EA3 and may cover the side surfaces of the first bank BNK1, the lower and side surfaces of the tips of the second bank BNK2, the side surfaces of the third and fourth banks BNK3 and BNK4, side surfaces of the third organic pattern ELP3, side surfaces of the third electrode pattern CEP3, and upper and side surfaces of the third capping pattern CLP3. The third inorganic layer TL3 may include an inorganic material to prevent oxygen or moisture from penetrating into the third light emitting element ED3. The third inorganic layer TL3 may be an inorganic encapsulation layer. For example, the third inorganic layer TL3 may be made of at least one of the materials exemplified in the description of the first inorganic layer TL1.

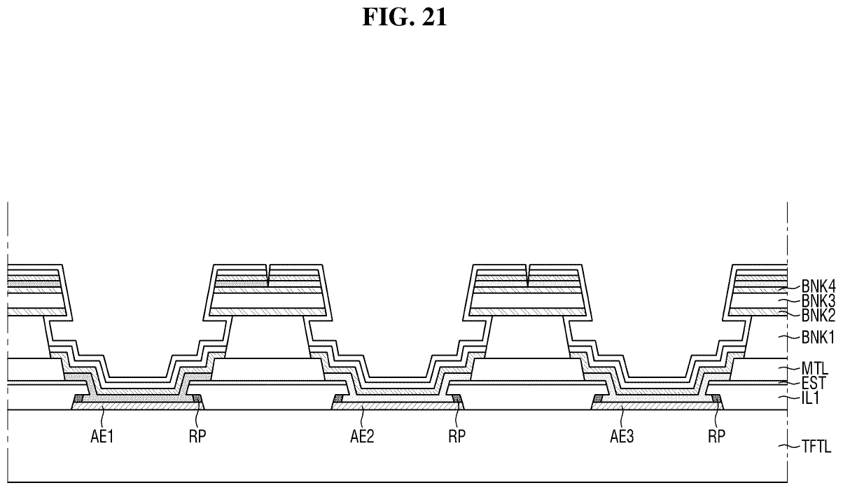

In FIG. 21, the third inorganic layer TL3, the third capping pattern CLP3, the third electrode pattern CEP3, and the third organic pattern ELP3 not disposed in the third emission area EA3 and an area adjacent to the third emission area EA3 may be etched through an etching process. For example, the third inorganic layer TL3, the third capping pattern CLP3, the third electrode pattern CEP3, and the third organic pattern ELP3 may be etched by performing at least one of a dry etching process and a wet etching process.

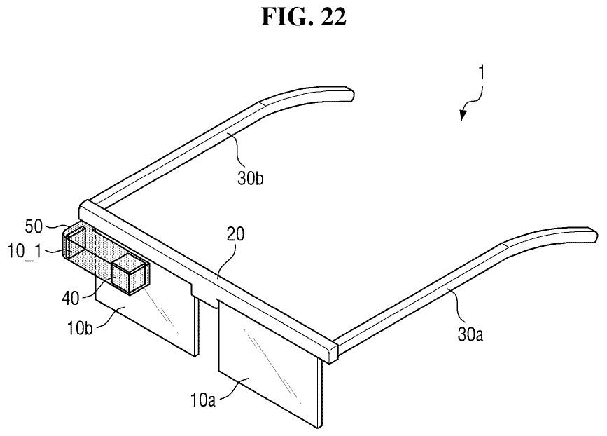

FIG. 22 illustrates a virtual reality device 1 including a display device 10_1 according to an embodiment. The display device 10_1 of FIG. 22 may include any one of the display devices 10 according to the embodiments of FIGS. 1 through 13 described above.

Referring to FIG. 22, the virtual reality device 1 may be a glasses-type display. The virtual reality device 1 may include the display device 10_1, a left lens 10a, a right lens 10b, a support frame 20, eyeglass frame legs 30a and 30b, a reflective member 40, and a display device housing 50.

Alternatively, the virtual reality device 1 may be applied to a head mounted display including a head mounted band that can be worn on the head instead of the eyeglass frame legs 30a and 30b. Therefore, the virtual reality device 1 is not limited to the one illustrated in FIG. 22 and can be applied in various forms to various other electronic devices.

The display device 10_1 and the reflective member 40 may be disposed in the display device housing 50. An image displayed on the display device 10_1 may be reflected by the reflective member 40 and provided to a user's right eye through the right lens 10b. Accordingly, the user can view a virtual reality image displayed on the display device 101 through the right eye.

The display device housing 50 may be disposed at a right end of the support frame 20. However, the position of the display device housing 50 is not limited thereto. For example, the display device housing 50 may also be disposed at a left end of the support frame 20. In this case, an image displayed on the display device 10_1 may be reflected by the reflective member 40 and provided to the user's left eye through the left lens 10a. Therefore, the user can view a virtual reality image displayed on the display device 10_1 through the left eye.

For another example, the display device housing 50 may be disposed at both the left end and the right end of the support frame 20. In this case, the user can view a virtual reality image displayed on the display device 10_1 through both the left eye and the right eye.

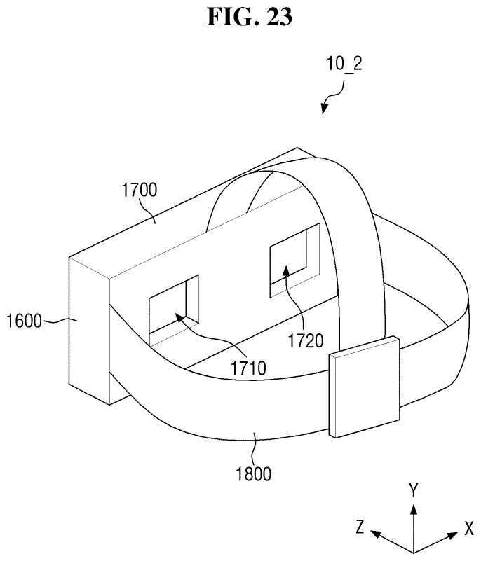

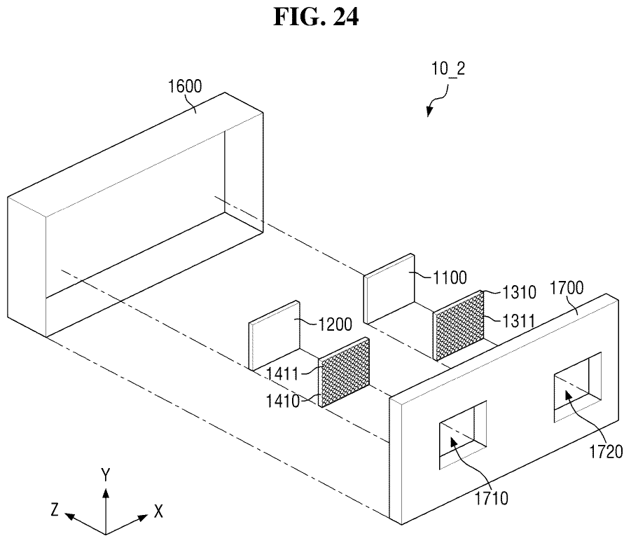

FIGS. 23 and 24 illustrate a head mounted display including a display device 10_2 according to an embodiment. The display device 10_2 of FIGS. 23 and 24 may include any one of the display devices 10 according to the embodiments of FIGS. 1 through 13 described above.

Referring to FIGS. 23 and 24, the display device 102 may be applied to a head mounted display. A first display device 1100 may provide an image to a user's right eye, and a second display device 1200 may provide an image to the user's left eye.

A first lens array 1310 may be disposed between the first display device 1100 and a housing cover 1700. The first lens array 1310 may include a plurality of lenses 1311. The lenses 1311 may include convex lenses that are convex toward the housing cover 1700.

A second lens array 1410 may be disposed between the second display device 1200 and the housing cover 1700. The second lens array 1410 may include a plurality of lenses 1411. The lenses 1411 may include convex lenses that are convex toward the housing cover 1700.

A display panel housing 1600 may accommodate the first display device 1100, the second display device 1200, the first lens array 1310, and the second lens array 1410. A surface of the display panel housing 1600 may be open to accommodate the first display device 1100, the second display device 1200, the first lens array 1310, and the second lens array 1410.

The housing cover 1700 may cover the open surface of the display panel housing 1600. The housing cover 1700 may include a first opening 1710 on which a user's left eye is placed and a second opening 1720 on which the user's right eye is placed. For example, the first opening 1710 and the second opening 1720 may be formed in a square shape, but the shapes of the first and second openings 1710 and 1720 are not limited thereto. For another example, the first and second openings 1710 and 1720 may be formed in a circular or oval shape. For another example, the first and second openings 1710 and 1720 may be integrated to form one opening.

The second opening 1720 may be aligned with the first display device 1100 and the first lens array 1310, and the first opening 1710 may be aligned with the second display device 1200 and the second lens array 1410. Therefore, a user can view an image of the first display device 1100, which is enlarged as a virtual image by the first lens array 1310, through the second opening 1720 and can view an image of the second display device 1200, which is enlarged as a virtual image by the second lens array 1410, through the first opening 1710.

A head mounted band 1800 may fix the display panel housing 1600 to a user's head so that the first opening 1710 and the second opening 1720 of the housing cover 1700 are placed on the user's left and right eyes, respectively. The head mounted band 1800 may be connected to upper, left, and right surfaces of the display panel housing 1600.

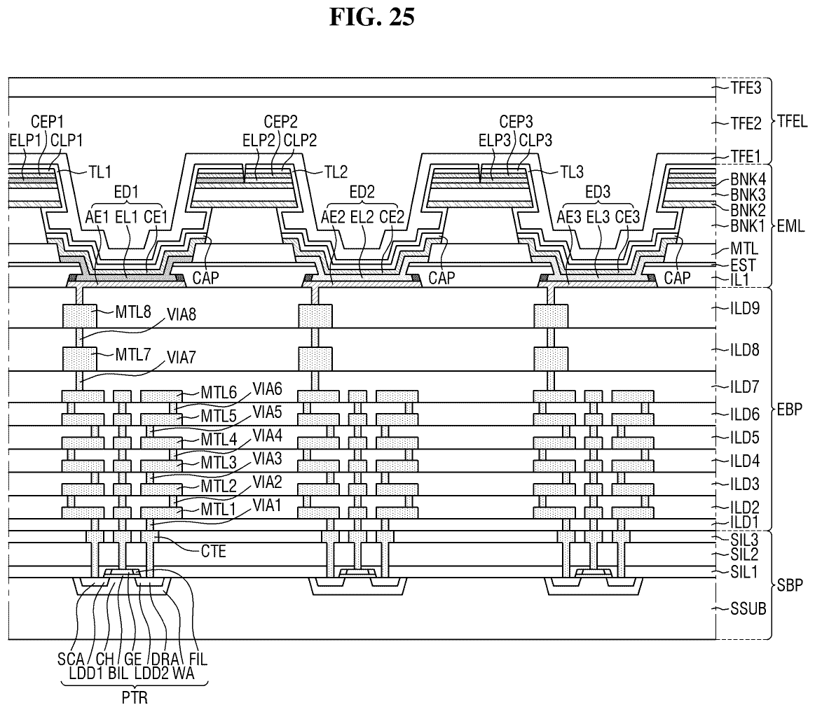

FIG. 25 is a cross-sectional view illustrating pixels according to an embodiment in the display devices of FIGS. 22 through 24. A display device 10 of FIG. 25 may include the light emitting element layer EML and the encapsulation layer TFEL the same as the light emitting element layer EML and the encapsulation layer TFEL described in FIG. 4. The same elements as those described above will be briefly described or will not be described.

Referring to FIG. 25, a display panel 100 may include a semiconductor backplane SBP, an emission backplane EBP, the light emitting element layer EML, and the encapsulation layer TFEL.

The semiconductor backplane SBP may include a semiconductor substrate SSUB, first through third semiconductor insulating layers SIL1 through SIL3, and contact terminals CTE.

The semiconductor substrate SSUB may be a silicon substrate, a germanium substrate, or a silicon-germanium substrate. The semiconductor substrate SSUB may be a substrate doped with first-type impurities. A plurality of well areas WA may be disposed in an upper portion of the semiconductor substrate SSUB. The well areas WA may be areas doped with second-type impurities different from the first-type impurities. For example, when the first-type impurities are p-type impurities, the second-type impurities may be n-type impurities. For another example, when the first-type impurities are n-type impurities, the second-type impurities may be p-type impurities.

A plurality of pixel transistors PTR each of which may include a well area WA, a source area SCA, a drain area DRA, a channel area CH, a first lightly doped impurity area LDD1, a second lightly doped impurity area LDD2, a bottom insulating layer BIL, a gate electrode GE, and a side insulating layer FIL.

The well area WA may be disposed in an upper portion of the semiconductor substrate SSUB. The source area SCA, the drain area DRA, the channel area CH, the first lightly doped impurity area LDD1, and the second lightly doped impurity area LDD2 may be disposed in the well area WA.

The source area SCA may correspond to a source electrode of a pixel transistor PTR, and the drain area DRA may correspond to a drain electrode of the pixel transistor PTR. Each of the source area SCA and the drain area DRA may be doped with the first-type impurities. The source area SCA may be disposed on one side of the gate electrode GE, and the drain area DRA may be disposed on the other side of the gate electrode GE.

The channel area CH may be disposed between the source area SCA and the drain area DRA. The bottom insulating layer BIL may be disposed on the channel area CH to insulate the channel area CH from the gate electrode GE. The gate electrode GE may be disposed on the bottom insulating layer BIL. The gate electrode GE may overlap the channel area CH and the well area WA in the thickness direction. The side insulating layer FIL (a spacer) may be disposed on side surfaces of the gate electrode GE and an upper surface of the bottom insulating layer BIL.

The first lightly doped impurity area LDD1 may be disposed between the channel area CH and a heavily doped impurity area (the source area SCA), and the second lightly doped impurity area LDD2 may be disposed between the channel area CH and a heavily doped impurity area (the drain area DRA). The first lightly doped impurity area LDD1 may have a lower impurity concentration than the source area SCA due to the side insulating layer FIL (the spacer). The second lightly doped impurity area LDD2 may have a lower impurity concentration than the drain area DRA due to the side insulating layer FIL (the spacer). A distance between the source area SCA and the drain area DRA may be increased by the first lightly doped impurity area LDD1 and the second lightly doped impurity area LDD2. Accordingly, a length of the channel area CH of the pixel transistor PTR may increase, thereby preventing punch-through and hot carrier phenomena caused by a short channel.

The first semiconductor insulating layer SIL1 may be disposed on the semiconductor substrate SSUB. The first semiconductor insulating layer SIL1 may include, but is not limited to, a silicon carbon nitride (SiCN) or silicon oxide (SiOx)-based inorganic layer.

The second semiconductor insulating layer SIL2 may be disposed on the first semiconductor insulating layer SILL. The second semiconductor insulating layer SIL2 may include, but is not limited to, a silicon oxide (SiOx)-based inorganic layer.

The contact terminals CTE may be disposed on the second semiconductor insulating layer SIL2. Each of the contact terminals CTE may be connected to one of the gate electrode GE, the source area SCA, and the drain area DRA of a pixel transistor PTR through a contact hole formed through the first semiconductor insulating layer SIL1 and the second semiconductor insulating layer SIL2. The contact terminals CTE may include at least one of copper (Cu), aluminum (Al), tungsten (W), molybdenum (Mo), chromium (Cr), gold (Au), titanium (Ti), nickel (Ni), and neodymium (Nd).

The third semiconductor insulating layer SIL3 may be disposed on side surfaces of each of the contact terminals CTE. An upper surface of each of the contact terminals CTE may be exposed without being covered by the third semiconductor insulating layer SIL3. The third semiconductor insulating layer SIL3 may include, but is not limited to, a silicon oxide (SiOx)-based inorganic layer.

The emission backplane EBP may include first through eighth metal layers MTL1 through MTL8, first through eighth vias VIA1 through VIA8, and first through ninth interlayer insulating layers ILD1 through ILD9.

The first through eighth metal layers MTL1 through MTL8 may be electrically connected to the contact terminals CTE exposed in the semiconductor backplane SBP to form each pixel circuit. For example, the semiconductor backplane SBP may include a plurality of pixel transistors PTR, and the emission backplane EBP may include a connection electrode connecting the pixel transistors PTR and at least one capacitor connected to each of the pixel transistors PTR. The emission backplane EBP may electrically connect a pixel circuit to a first light emitting element ED1.

The first interlayer insulating layer ILD1 may be disposed on the semiconductor backplane SBP. The first vias VIA1 may be formed through the first interlayer insulating layer ILD1 and may be connected to the contact terminals CTE exposed in the semiconductor backplane SBP. The first metal layers MTL1 may be disposed on the first interlayer insulating layer ILD1 and connected to the first vias VIA1.

The second interlayer insulating layer ILD2 may be disposed on the first interlayer insulating layer IND1 and the first metal layers MTL1. The second vias VIA2 may be formed through the second interlayer insulating layer ILD2 and may be connected to the first metal layers MTL1. The second metal layers MTL2 may be disposed on the second interlayer insulating layer ILD2 and connected to the second vias VIA2.

The third interlayer insulating layer ILD3 may be disposed on the second interlayer insulating layer ILD2 and the second metal layers MTL2. The third vias VIA3 may be formed through the third interlayer insulating layer ILD3 and may be connected to the second metal layers MTL2. The third metal layers MTL3 may be disposed on the third interlayer insulating layer ILD3 and connected to the third vias VIA3.

The fourth interlayer insulating layer ILD4 may be disposed on the third interlayer insulating layer ILD3 and the third metal layers MTL3. The fourth vias VIA4 may be formed through the fourth interlayer insulating layer ILD4 and may be connected to the third metal layers MTL3. The fourth metal layers MTL4 may be disposed on the fourth interlayer insulating layer ILD4 and connected to the fourth vias VIA4.

The fifth interlayer insulating layer ILD5 may be disposed on the fourth interlayer insulating layer ILD4 and the fourth metal layers MTL4. The fifth vias VIA5 may be formed through the fifth interlayer insulating layer ILD5 and may be connected to the fourth metal layers MTL4. The fifth metal layers MTL5 may be disposed on the fifth interlayer insulating layer ILD5 and connected to the fifth vias VIA5.

The sixth interlayer insulating layer ILD6 may be disposed on the fifth interlayer insulating layer ILD5 and the fifth metal layers MTL5. The sixth vias VIA6 may be formed through the sixth interlayer insulating layer ILD6 and may be connected to the fifth metal layers MTL5. The sixth metal layers MTL6 may be disposed on the sixth interlayer insulating layer ILD6 and connected to the sixth vias VIA6.

The seventh interlayer insulating layer IND7 may be disposed on the sixth interlayer insulating layer ILD6 and the sixth metal layers MTL6. The seventh vias VIA7 may be formed through the seventh interlayer insulating layer ILD7 and may be connected to the sixth metal layers MTL6. The seventh metal layers MTL7 may be disposed on the seventh interlayer insulating layer ILD7 and connected to the seventh vias VIA7.

The eighth interlayer insulating layer IND8 may be disposed on the seventh interlayer insulating layer ILD7 and the seventh metal layers MTL7. The eighth vias VIA8 may be formed through the eighth interlayer insulating layer ILD8 and may be connected to the seventh metal layers MTL7. The eighth metal layers MTL8 may be disposed on the eighth interlayer insulating layer ILD8 and connected to the eighth vias VIA8. The ninth interlayer insulating layer ILD9 may be disposed on the eighth interlayer insulating layer ILD8 and the eighth metal layers MTL8.

The first through eighth metal layers MTL1 through MTL8 and the first through eighth vias VIA1 through VIA8 may include substantially the same material. The first through eighth metal layers MTL1 through MTL8 and the first through eighth vias VIA1 through VIA8 may include at least one of copper (Cu), aluminum (Al), tungsten (W), molybdenum (Mo), chromium (Cr), gold (Au), titanium (Ti), nickel (Ni), and neodymium (Nd). Each of the first through ninth interlayer insulating layers ILD1 through ILD9 may include, but is not limited to, a silicon oxide (SiOx)-based inorganic layer.

A thickness of the first metal layers MTL1, a thickness of the second metal layers MTL2, a thickness of the third metal layers MTL3, a thickness of the fourth metal layers MTL4, a thickness of the fifth metal layers MTL5, and a thickness of the sixth metal layers MTL6 may each be greater than each of a thickness of the first vias VIA1, a thickness of the second vias VIA2, a thickness of the third vias VIA3, a thickness of the fourth vias VIA4, a thickness of the fifth vias VIA5, and a thickness of the sixth vias VIA6. The thickness of the second metal layers MTL2, the thickness of the third metal layers MTL3, the thickness of the fourth metal layers MTL4, the thickness of the fifth metal layers MTL5, and the thickness of the sixth metal layers MTL6 may each be greater than the thickness of the first metal layers MTL1. The thickness of the second metal layers MTL2, the thickness of the third metal layers MTL3, the thickness of the fourth metal layers MTL4, the thickness of the fifth metal layers MTL5, and the thickness of the sixth metal layers MTL6 may be substantially the same. For example, the thickness of the first metal layers MTL1 may be about 1360 Å, the thickness of the second metal layers MTL2, the thickness of the third metal layers MTL3, the thickness of the fourth metal layers MTL4, the thickness of the fifth metal layers MTL5 and the thickness of the sixth metal layers MTL6 may each be about 1440 Å, and the thickness of the first vias VIA1, the thickness of the second vias VIA2, the thickness of the third vias VIA3, the thickness of the fourth vias VIA4, the thickness of the fifth vias VIA5 and the thickness of the sixth vias VIA6 may each be about 1150 Å.

A thickness of the seventh metal layers MTL7 and a thickness of the eighth metal layers MTL8 may each be greater than each of the thickness of the first metal layers MTL1, the thickness of the second metal layers MTL2, the thickness of the third metal layers MTL3, the thickness of the fourth metal layers MTL4, the thickness of the fifth metal layers MTL5, and the thickness of the sixth metal layers MTL6. The thickness of the seventh metal layers MTL7 and the thickness of the eighth metal layers MTL8 may each be greater than each of a thickness of the seventh vias VIA7 and a thickness of the eighth vias VIA8. The thickness of the seventh vias VIA7 and the thickness of the eighth vias VIA8 may each be greater than each of the thickness of the first vias VIA1, the thickness of the second vias VIA2, the thickness of the third vias VIA3, the thickness of the fourth vias VIA4, the thickness of the fifth vias VIA5, and the thickness of the sixth vias VIA6. The thickness of the seventh metal layers MTL7 and the thickness of the eighth metal layers MTL8 may be substantially the same. For example, the thickness of the seventh metal layers MTL7 and the thickness of the eighth metal layers MTL8 may each be about 9000 Å. The thickness of the seventh vias VIA7 and the thickness of the eighth vias VIA8 may each be about 6000 Å.

The display device 10 may include a large number of pixels SP in a relatively small area as its resolution increases. The emission backplane EBP including the first through eighth metal layers MTL1 through MTL8 may implement a connection electrode connecting the pixel transistors PTR and at least one capacitor connected to each of the pixel transistors PTR, thereby implementing pixel circuits in a relatively small area. Therefore, the light emitting element layer EML can be formed on a silicon wafer (Si-wafer) including the semiconductor backplane SBP and the emission backplane EBP, and the display device 10 can realize ultra-high resolution image quality.

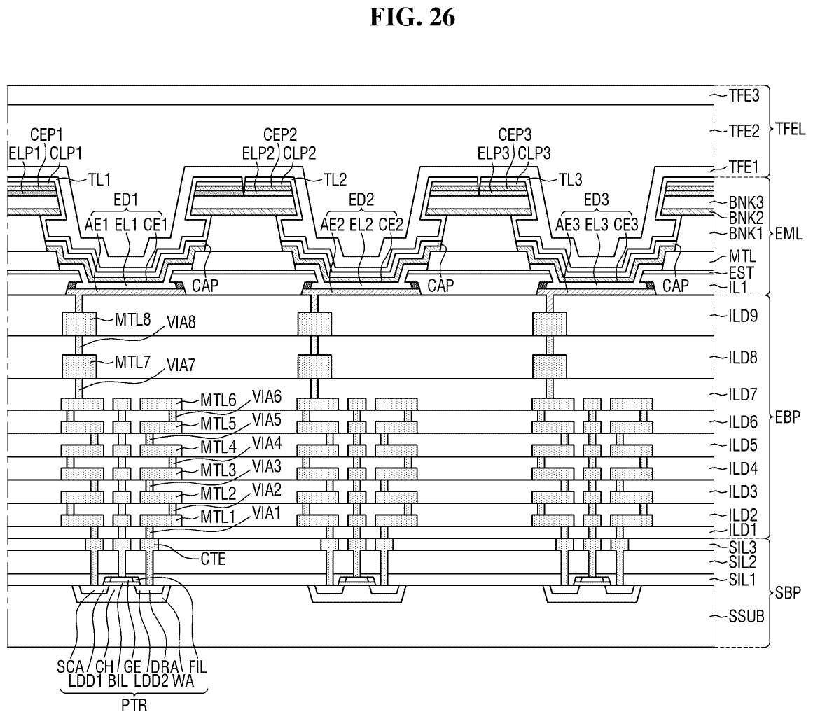

FIG. 26 is a cross-sectional view illustrating pixels according to an embodiment in the display devices of FIGS. 22 through 24. A display device of FIG. 26 may include the semiconductor backplane SBP and the emission backplane EBP the same as the semiconductor backplane SBP and the emission backplane EBP of FIG. 25 and may include the light emitting element layer EML and the encapsulation layer TFEL the same as the light emitting element layer EML and the encapsulation layer TFEL of FIG. 6. Therefore, a description of the display device of FIG. 26 will be omitted.

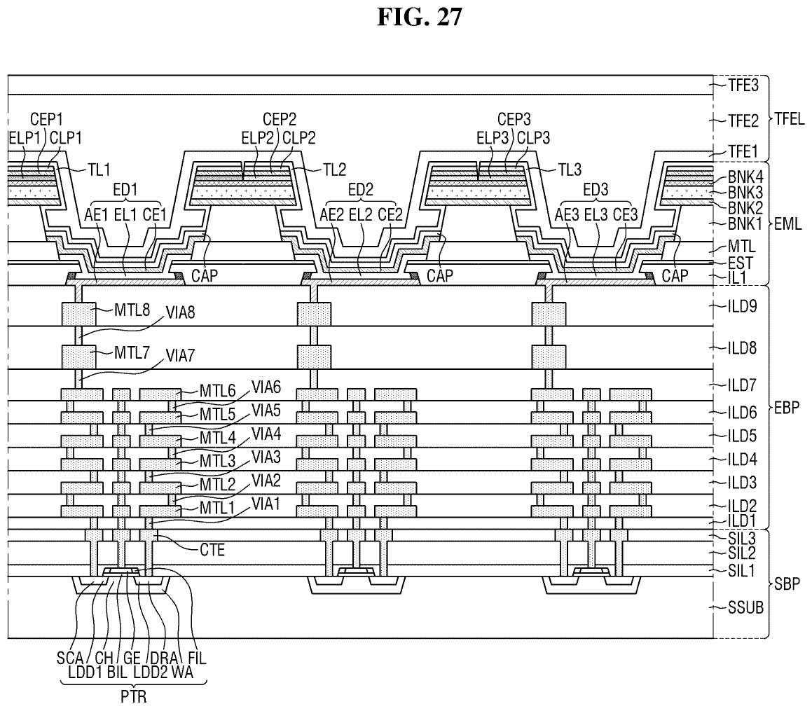

FIG. 27 is a cross-sectional view illustrating pixels according to an embodiment in the display devices of FIGS. 22 through 24. A display device of FIG. 27 may include the semiconductor backplane SBP and the emission backplane EBP the same as the semiconductor backplane SBP and the emission backplane EBP of FIG. 25 and may include the light emitting element layer EML and the encapsulation layer TFEL the same as the light emitting element layer EML and the encapsulation layer TFEL of FIG. 8 as they are. Therefore, a description of the display device of FIG. 27 will be omitted.

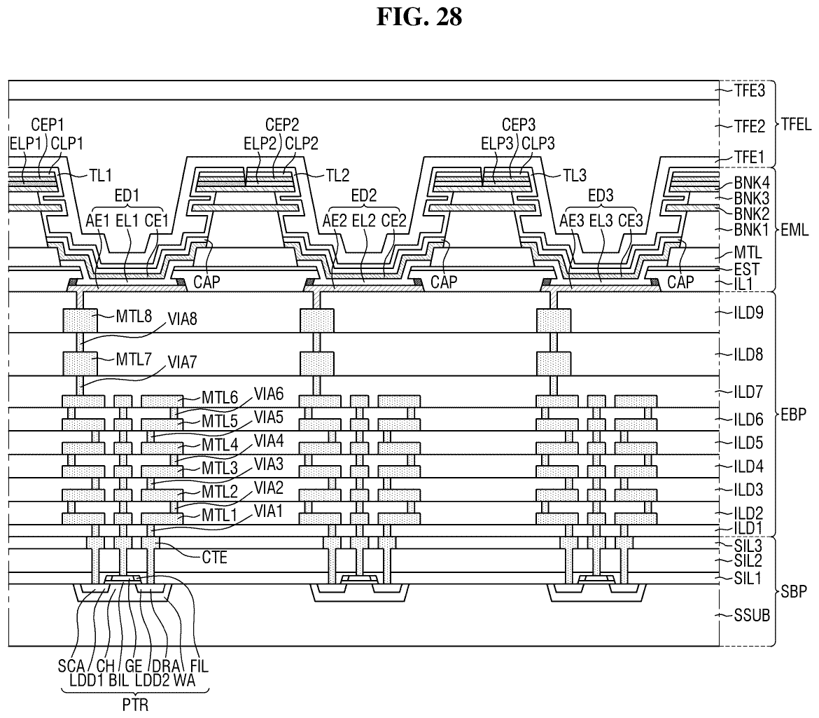

FIG. 28 is a cross-sectional view illustrating pixels according to an embodiment in the display devices of FIGS. 22 through 24. A display device of FIG. 28 may include the semiconductor backplane SBP and the emission backplane EBP the same as the light emitting element layer EML and the encapsulation layer TFEL of FIG. 25 and may include the light emitting element layer EML and the encapsulation layer TFEL the same as the light emitting element layer EML and the encapsulation layer TFEL of FIG. 10. Therefore, a description of the display device of FIG. 28 will be omitted.

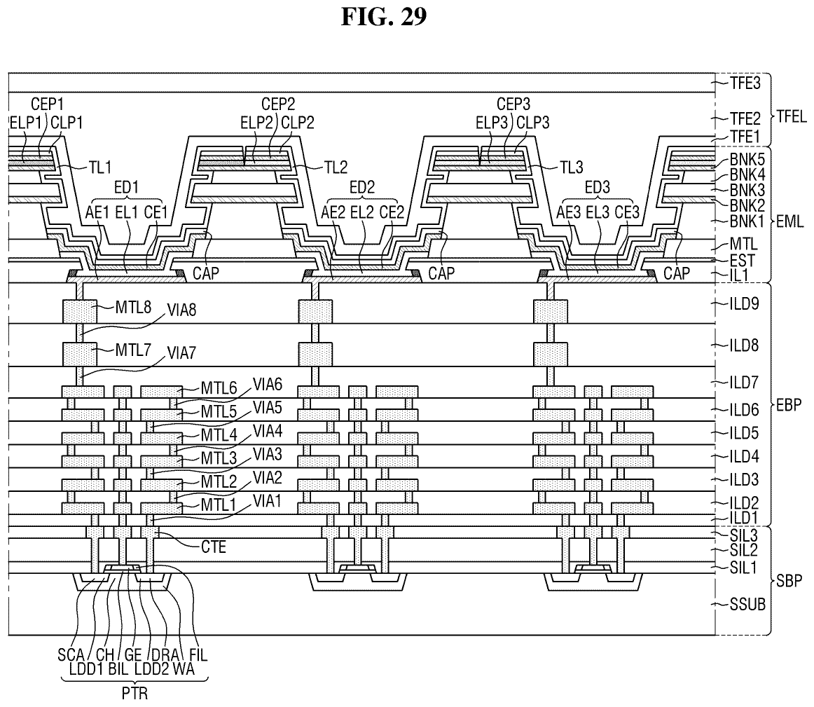

FIG. 29 is a cross-sectional view illustrating pixels according to an embodiment in the display devices of FIGS. 22 through 24. A display device of FIG. 29 may include the semiconductor backplane SBP and the emission backplane EBP the same as the semiconductor backplane SBP and the emission backplane EBP of FIG. 25 and may include the light emitting element layer EML and the encapsulation layer TFEL the same as the light emitting element layer EML and the encapsulation layer TFEL of FIG. 12. Therefore, a description of the display device of FIG. 29 will be omitted.

In a display device and a method of manufacturing the same according to embodiments, the thickness of a bank is increased to secure an area where an inorganic layer encapsulates the bank. Accordingly, a moisture penetration path is blocked, thereby improving the reliability of light emitting elements.

However, the effects of the present disclosure are not restricted to the one set forth herein. The above and other effects of the present disclosure will become more apparent to one of daily skill in the art to which the present disclosure pertains by referencing the claims.

What is claimed is:

1. A display device comprising:
a first pixel electrode disposed on a substrate in a first emission area;
an insulating layer covering edges of the first pixel electrode;
a first light emitting layer disposed on the first pixel electrode and the insulating layer;
a first common electrode disposed on the first light emitting layer;
a conductive layer disposed on the insulating layer to surround the first emission area and contact the first common electrode;
a first bank disposed on the conductive layer;
a second bank disposed on the first bank and including tips protruding from side surfaces of the first bank toward the first emission area; and
a third bank disposed on the second bank and including an inorganic material.

2. The display device of claim 1, further comprising a fourth bank disposed on the third bank and including a metal material.

3. The display device of claim 2, wherein a thickness of the first bank is greater than the sum of thicknesses of the second bank, the third bank, and fourth bank, and the thickness of the third bank is greater than the thickness of each of the second and fourth banks.

4. The display device of claim 2, further comprising:
a first organic pattern including the same material as the first light emitting layer and disposed on the fourth bank in an area adjacent to the first emission area; and
a first electrode pattern including the same material as the first common electrode and disposed on the first organic pattern on the fourth bank.

5. The display device of claim 4, further comprising:
a capping layer disposed on the first common electrode; and
a first capping pattern including the same material as the capping layer and disposed on the first electrode pattern.

6. The display device of claim 5, further comprising a first inorganic layer covering the side surfaces of the first bank, lower and side surfaces of the tips of the second bank, side surfaces of the third and fourth banks, side surfaces of the first organic pattern, side surfaces of the first electrode pattern, and upper and side surfaces of the first capping pattern.

7. The display device of claim 2, further comprising:
a second pixel electrode disposed on the substrate in a second emission area;
a second light emitting layer disposed on the second pixel electrode; and
a second common electrode disposed on the second light emitting layer to contact the conductive layer.

8. The display device of claim 7, wherein the first and second common electrodes are electrically connected through the conductive layer.

9. The display device of claim 7, further comprising:
a capping layer disposed on the second common electrode;
a second organic pattern including the same material as the second light emitting layer and disposed on the fourth bank in an area adjacent to the second emission area;
a second electrode pattern including the same material as the second common electrode and disposed on the second organic pattern on the fourth bank; and
a second capping pattern including the same material as the capping layer and disposed on the second electrode pattern.

10. The display device of claim 9, further comprising a second inorganic layer covering the side surfaces of the first bank, the lower and side surfaces of the tips of the second bank, the side surfaces of the third and fourth banks, side surfaces of the second organic pattern, side surfaces of the second electrode pattern, and upper and side surfaces of the second capping pattern.

11. The display device of claim 1, further comprising:
a capping layer disposed on the first common electrode;
a first organic pattern including the same material as the first light emitting layer and disposed on the third bank in an area adjacent to the first emission area;
a first electrode pattern including the same material as the first common electrode and disposed on the first organic pattern on the third bank; and
a first capping pattern including the same material as the capping layer and disposed on the first electrode pattern.

12. The display device of claim 1, further comprising a fourth bank disposed on the third bank and including a different inorganic material from the third bank.

13. The display device of claim 1, further comprising:
a fourth bank disposed on the third bank; and
a fifth bank disposed on the fourth bank and protruding from side surfaces of the fourth bank toward the first emission area.

14. A display device comprising:
a first pixel electrode disposed on a substrate in a first emission area;
a second pixel electrode disposed on the same layer as the first pixel electrode in a second emission area;
an insulating layer covering edges of each of the first and second pixel electrodes;
a first light emitting layer disposed on the first pixel electrode and the insulating layer;
a first common electrode disposed on the first light emitting layer;
a second light emitting layer disposed on the second pixel electrode and the insulating layer;
a second common electrode disposed on the second light emitting layer;
a conductive layer disposed on the insulating layer to surround each of the first and second emission areas and electrically connect the first and second common electrodes;
a first bank disposed on the conductive layer;
a second bank disposed on the first bank and including tips protruding from side surfaces of the first bank toward each of the first and second emission areas;
a third bank disposed on the second bank; and
a fourth bank disposed on the third bank and including tips protruding from side surfaces of the third bank toward each of the first and second emission areas.

15. The display device of claim 14, further comprising:
a capping layer disposed on the first common electrode;
a first organic pattern including the same material as the first light emitting layer and disposed on the fourth bank in an area adjacent to the first emission area;
a first electrode pattern including the same material as the first common electrode and disposed on the first organic pattern on the fourth bank;
a first capping pattern including the same material as the capping layer and disposed on the first electrode pattern; and
a first inorganic layer covering the side surfaces of the first bank, lower and side surfaces of the tips of the second bank, side surfaces of the third bank, lower and side surfaces of the tips of the fourth bank, side surfaces of the first organic pattern, side surfaces of the first electrode pattern, and upper and side surfaces of the first capping pattern.

16. The display device of claim 15, further comprising:
a capping layer disposed on the second common electrode;
a second organic pattern including the same material as the second light emitting layer and disposed on the fourth bank in an area adjacent to the second emission area;
a second electrode pattern including the same material as the second common electrode and disposed on the second organic pattern on the fourth bank;
a second capping pattern including the same material as the capping layer and disposed on the second electrode pattern; and
a second inorganic layer covering the side surfaces of the first bank, the lower and side surfaces of the tips of the second bank, the side surfaces of the third bank, lower and side surfaces of the tips of the fourth bank, side surfaces of the second organic pattern, side surfaces of the second electrode pattern, and upper and side surfaces of the second capping pattern.

17. A method of manufacturing a display device, the method comprising:
forming pixel electrodes and sacrificial layers on a substrate, the pixel electrodes including a first pixel electrode which overlaps a first emission area and a second pixel electrode which overlaps a second emission area;
sequentially stacking an insulating layer, a conductive layer, a first bank, a second bank, a third bank, and a fourth bank on the pixel electrodes;
forming tips of the second bank which protrude from side surfaces of the first bank by etching the fourth bank, the third bank, the second bank, the first bank, and the conductive layer;
exposing the first and second pixel electrodes by etching the insulating layer and the sacrificial layer;
forming a first light emitting layer on the first pixel electrode and a first organic pattern on the fourth bank;
forming a first common electrode on the first light emitting layer and a first electrode pattern on the first organic pattern on the fourth bank;
forming a capping layer on the first common electrode and a first capping pattern on the first electrode pattern on the fourth bank; and
forming a first inorganic layer which covers an upper surface of the capping layer, the side surfaces of the first bank, lower and side surfaces of the tips of the second bank, side surfaces of the third and fourth banks, side surfaces of the first organic pattern, side surfaces of the first electrode pattern, and upper and side surfaces of the first capping pattern.

18. The method of claim 17, wherein the third bank and the first inorganic layer include at least one of a silicon nitride layer, a silicon oxynitride layer, a silicon oxide layer, a titanium oxide layer, an aluminum oxide layer, and an amorphous silicon layer.

19. The method of claim 18, further comprising etching the first inorganic layer, the first capping pattern, the first electrode pattern, and the first organic pattern which overlap the second emission area and the fourth bank disposed adjacent to the second emission area.

20. The method of claim 19, further comprising:
forming a second light emitting layer on the second pixel electrode and a second organic pattern on the fourth bank;
forming a second common electrode on the second light emitting layer and a second electrode pattern on the second organic pattern on the fourth bank;
forming a capping layer on the second common electrode and a second capping pattern on the second electrode pattern on the fourth bank; and
forming a second inorganic layer which covers an upper surface of the capping layer, the side surfaces of the first bank, the lower and side surfaces of the tips of the second bank, the side surfaces of the third and fourth banks, side surfaces of the second organic pattern, side surfaces of the second electrode pattern, and upper and side surfaces of the second capping pattern.
